(19) United States
(12) Patent Application Publication
(10) Pub. No.: US 2026/0182154 A1
(43) Pub. Date: Jun. 25, 2026

(54) DISPLAY DEVICE AND ELECTRONIC DEVICE

(71) Applicant: Samsung Display Co., Ltd., Yongin-si, Gyeonggi-do (KR)

(72) Inventors: Hyun Eok SHIN, Yongin-si (KR); Ki Nyeng KANG, Yongin-si (KR); Keun Woo KIM, Yongin-si (KR)

(21) Appl. No.: 19/334,381

(22) Filed: Sep. 19, 2025

(30) Foreign Application Priority Data
Dec. 24, 2024 (KR) 10-2024-0195910

(51) Int. Cl. H10K 59/122; H10K 59/35; H10K 59/80

(52) U.S. Cl. CPC H10K 59/122; H10K 59/353; H10K 59/80521

(57) ABSTRACT

A display device includes a first electrode defining first openings, first light-emitting elements respectively in the first openings and configured to emit light in a first color, a second electrode defining second openings, second light-emitting elements respectively in the second openings and configured to emit light in a second color, a third electrode defining third openings, and third light-emitting elements respectively in the third openings and configured to emit light in a third color, wherein the first electrode, the second electrode, and the third electrode are separated from each other and are electrically disconnected.

### CROSS-REFERENCE TO RELATED APPLICATION

The present application claims priority to, and the benefit of, Korean Patent Application No. 10-2024-0195910, filed on Dec. 24, 2024, in the Korean Intellectual Property Office, the entire disclosure of which is incorporated herein by reference.

### BACKGROUND

### 1. Field

Embodiments of the present disclosure relate to a display device and an electronic device.

### 2. Description of the Related Art

Recently, as interest in information display has increased, research and development on display devices are continuously being conducted.

### SUMMARY

The present disclosure provides a display device and an electronic device capable of independently providing a cathode voltage for each pixel.

A display device according to embodiments of the present disclosure includes a first electrode defining first openings, first light-emitting elements respectively in the first openings and configured to emit light in a first color, a second electrode defining second openings, second light-emitting elements respectively in the second openings and configured to emit light in a second color, a third electrode defining third openings, and third light-emitting elements respectively in the third openings and configured to emit light in a third color, wherein the first electrode, the second electrode, and the third electrode are separated from each other and are electrically disconnected.

The first light-emitting elements may be configured to receive a first voltage through the first electrode, wherein the second light-emitting elements are configured to receive a second voltage through the second electrode, and wherein the third light-emitting elements are configured to receive a third voltage through the third electrode.

There might be no electrode between the first electrode and the second electrode or between the second electrode and the third electrode in a plan view.

In a plan view, the first electrode, the second electrode, and the third electrode may be sequentially arranged along a first direction, and extend in a second direction crossing the first direction, wherein the first openings, the second openings, and the third openings are arranged along the second direction, and wherein, in a plan view, the first electrode surrounds only the first light-emitting elements, the second electrode surrounds only the second light-emitting elements, and the third electrode surrounds only the third light-emitting elements.

In a plan view, the first electrode, the second electrode, and the third electrode may be sequentially and repeatedly arranged along a first direction, and extend in a second direction crossing the first direction, wherein the first openings, the second openings, and the third openings are arranged along the second direction.

The first light-emitting element, the second light-emitting element, and the third light-emitting element may include an anode electrode, a light-emitting layer above the anode electrode, and a cathode electrode above the light-emitting layer, wherein the first electrode contacts the cathode electrode of the first light-emitting elements, wherein the second electrode contacts the cathode electrode of the second light-emitting elements, wherein the third electrode contacts the cathode electrode of the third light-emitting elements, wherein the display device further includes an encapsulation layer above the cathode electrode at the first opening, the second opening, and the third opening, an organic layer above and covering the encapsulation layer, and a pixel-defining layer above the anode electrode and defining openings corresponding to the first opening, the second opening, and the third opening, and wherein the organic layer fills between the first electrode, the second electrode, and the third electrode, and contacts the pixel-defining layer between the first electrode, the second electrode, and the third electrode.

The first light-emitting elements may correspond one-to-one with the first openings, wherein the second light-emitting elements correspond one-to-one with the second openings, and wherein the third light-emitting elements correspond one-to-one with the third openings.

The first light-emitting element, the second light-emitting element, and the third light-emitting element may include an organic light-emitting diode.

A display device according to embodiments of the present disclosure includes a first electrode defining first openings, first light-emitting elements respectively in the first openings and configured to emit light in a first color, a second electrode defining second openings and third openings, and electrically separated from the first electrode, second light-emitting elements respectively in the second openings and configured to emit light in a second color, and third light-emitting elements respectively in the third openings and configured to emit light in a third color.

The first light-emitting elements may emit light in blue, wherein the second light-emitting elements emit light in red, and wherein the third light-emitting elements emit light in green.

In a plan view, the first electrode and the second electrode may be spaced apart from each other in a first direction, and extend in a second direction crossing the first direction, wherein the first openings, the second openings, and the third openings are arranged along the second direction.

The first electrode and the second electrode may be alternately and repeatedly arranged along the first direction, wherein the first electrode is connected to another first electrode at one end, and wherein the second electrode is connected to another second electrode at another end.

The second openings and the third openings may be alternately arranged along the second direction.

The first light-emitting element, the second light-emitting element, and the third light-emitting element may include an anode electrode, a light-emitting layer above the anode electrode, and a cathode electrode above the light-emitting layer, wherein the first electrode contacts the cathode electrode of the first light-emitting elements, wherein the second electrode contacts the cathode electrode of the second and third light-emitting elements, and wherein the display device further includes a pixel-defining layer above the anode electrode and defining openings corresponding to the first opening, the second opening, and the third opening, an encapsulation layer above the cathode electrode at the first opening, the second opening, and the third opening, and an organic layer above the encapsulation layer and covering the encapsulation layer, and wherein the organic layer fills between the first electrode and the second electrode and contacts the pixel-defining layer.

An electronic device according to embodiments of the present disclosure includes a processor configured to provide image data, and a display device configured to display an image based on the image data, and including a first electrode defining first openings, first light-emitting elements respectively in the first openings and configured to emit light in a first color, a second electrode defining second openings and electrically separated from the first electrode, and a second light-emitting element respectively in the second openings and configured to emit light in a second color.

The first and second light-emitting elements may include an anode electrode, a light-emitting layer above the anode electrode, and a cathode electrode above the light-emitting layer, wherein the first electrode contacts the cathode electrode of the first light-emitting elements, wherein the second electrode contacts the cathode electrode of the second light-emitting elements, and wherein the electronic device further includes a pixel-defining layer above the anode electrode and defining openings corresponding to the first and second openings, an encapsulation layer above the cathode electrode at the first and second openings, and an organic layer above the encapsulation layer, covering the encapsulation layer, filling between the first electrode and the second electrode, and contacting the pixel-defining layer.

The electronic device may further include a third electrode defining third openings and electrically separated from the first electrode and the second electrode, and third light-emitting elements respectively in the third openings and configured to emit light in a third color, wherein, in a plan view, the first electrode, the second electrode, and the third electrode are sequentially arranged along a first direction, and extend in a second direction crossing the first direction, and wherein the first openings, the second openings, and the third openings are arranged along the second direction.

The electronic device may further include third light-emitting elements respectively in third openings defined in the second electrode and configured to emit light in green, wherein the first light-emitting elements emit light in blue, and wherein the second light-emitting elements emit light in red.

The electronic device may further include third light-emitting elements respectively in third openings defined in the second electrode and configured to emit light in a third color, wherein, in a plan view, the first electrode and the second electrode are spaced apart from each other and alternately and repeatedly arranged in a first direction, and extend in a second direction crossing the first direction, wherein the first openings, the second openings, and the third openings are arranged along the second direction, wherein the first electrode is connected to another first electrode at one end, and wherein the second electrode is connected to another second electrode at another end.

The electronic device may further include third light-emitting elements respectively in third openings defined in the second electrode and configured to emit light in a third color, wherein, in a plan view, the first electrode and the second electrode are spaced apart from each other in a first direction, and extend in a second direction crossing the first direction, and wherein the first openings, the second openings, and the third openings are arranged along the second direction, the second openings and the third openings being alternately arranged along the second direction.

In a display device and an electronic device according to embodiments of the present disclosure, a first electrode (or a first partition wall) surrounding first light-emitting elements and a second electrode (or a second partition wall) surrounding second light-emitting elements are separated from each other (e.g., in plan view), and different voltages (or cathode voltages) may be provided to the first light-emitting elements and the second light-emitting elements. Accordingly, power consumption may be reduced or improved.

Aspects of embodiments of the present disclosure are not limited by what is explained or illustrated above, and more various aspects of the present disclosure will be described in detail in the following.

### BRIEF DESCRIPTION OF THE DRAWINGS

FIG. 1 is a block diagram illustrating a display device according to embodiments.

FIG. 2 is a block diagram illustrating one or more embodiments of a sub-pixel included in the display device of FIG. 1.

FIG. 3 is a circuit diagram illustrating one or more embodiments of the sub-pixel of FIG. 2.

FIG. 4 is a plan view illustrating one or more embodiments of a display unit included in the display device of FIG. 1.

FIGS. 5 and 6 are plan views illustrating one or more embodiments of the display panel of FIG. 4.

FIG. 7 is a cross-sectional view illustrating one or more embodiments of a display panel along the line A-A′ of FIG. 5.

FIG. 8 is a cross-sectional view illustrating one or more embodiments of a display panel along the line B-B′ of FIG. 5.

FIG. 9 is an enlarged view of an area AA of FIG. 8.

FIG. 10 is a cross-sectional view illustrating one or more embodiments of a display panel along the line C-C′ of FIG. 5.

FIGS. 11 and 12 are plan views illustrating one or more other embodiments of the display panel of FIG. 4.

FIG. 13 is a cross-sectional view illustrating one or more embodiments of a display panel along the line D-D′ of FIG. 11.

FIG. 14 is a cross-sectional view illustrating one or more embodiments of a display panel along the line E-E′ of FIG. 11.

FIGS. 15A to 15D are plan views illustrating one or more other embodiments of the display panel of FIG. 4.

FIGS. 15E and 15F are cross-sectional views illustrating one or more embodiments of a display panel along the line K-K′ of FIG. 15C.

FIGS. 16A to 16I are plan views illustrating one or more other embodiments of the display panel of FIG. 4.

FIGS. 17 to 24 are cross-sectional views of a process step of a method of manufacturing a display device according to one or more embodiments.

FIG. 25 is a block diagram of an electronic device according to one or more embodiments.

FIG. 26 is a schematic diagram of an electronic device according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

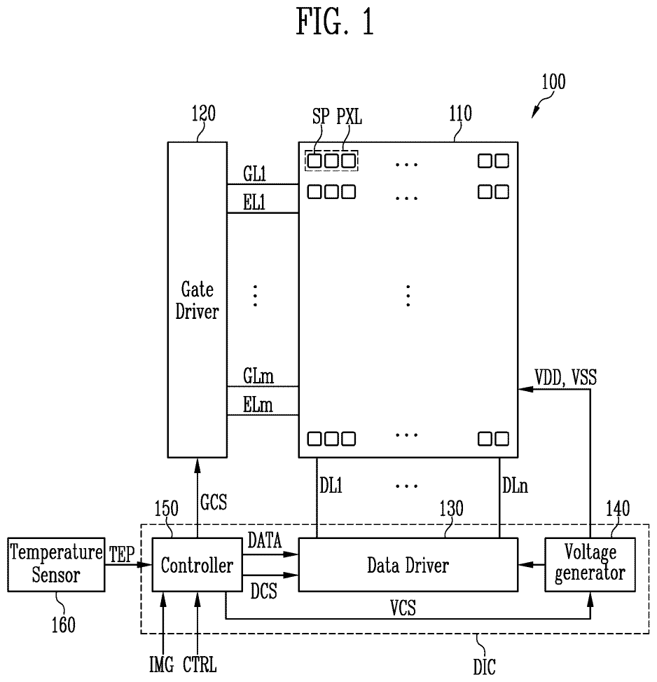

FIG. 1 is a block diagram illustrating a display device according to embodiments.

Referring to FIG. 1, a display device 100 may include a display unit 110 (or a display panel), a gate driver 120, a data driver 130, a voltage generator 140, and a controller 150.

The display unit 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Each of the sub-pixels SP may generate light of a corresponding color, such as red, green, blue, cyan, magenta, yellow, or the like. Two or more sub-pixels of the sub-pixels SP may constitute a pixel PXL. For example, as shown in FIG. 1, three sub-pixels may constitute the pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating a start of each frame, a horizontal synchronization signal for outputting the gate signals in synchronization with timing at which data signals are applied, and the like.

In one or more embodiments, first to m-th light emission control lines EL1 to ELm connected to the sub-pixels SP in the row direction may be further provided. In this case, the gate driver 120 may include a light emission control driver configured to control the first to m-th light emission control lines EL1 to ELm, and the light emission control driver may operate according to control of the controller 150.

The gate driver 120 may be located on one side of the display unit 110. However, embodiments are not limited thereto. For example, the gate driver 120 may be divided into two or more drivers that are physically and/or logically divided, and such drivers may be located on one side of the display unit 110 and another side of the display unit 110 opposite to the one side. As such, the gate driver 120 may be located around the display unit 110 in various forms.

The data driver 130 is connected to the sub-pixels SP arranged in a column direction through the first to n-th data lines DL1 to DLn. The data driver 130 receives image data DATA and the data control signal DCS from the controller 150. The data driver 130 operates in response to the data control signal DCS. In one or more embodiments, the data control signal DCS may include a source start pulse, a source shift clock, a source output enable signal, and the like.

The data driver 130 may use voltages provided from the voltage generator 140 to apply the data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals, and an image is displayed on the display unit 110.

In one or more embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate voltages and provide the generated voltages to components of the display device 100. For example, the voltage generator 140 may be configured to generate voltages by receiving an input voltage from outside the display device 100, adjusting the received voltage, and regulating the adjusted voltage.

The voltage generator 140 may generate a first power voltage VDD and a second power voltage VSS, and the first and second power voltages VDD and VSS may be provided to the sub-pixels SP. The first power voltage VDD may have a relatively high voltage level, and the second power voltage VSS may have a lower voltage level than the first power voltage VDD. In one or more other embodiments, the first power voltage VDD or the second power voltage VSS may be provided by an external device of the display device 100.

The voltage generator 140 may generate various voltages. For example, the voltage generator 140 may generate an initialization voltage applied to the sub-pixels SP. For example, in a sensing operation for sensing electrical characteristics of transistors and/or light-emitting elements of the sub-pixels SP, a reference voltage may be applied to the first to n-th data lines DL1 to DLn, and the voltage generator 140 may generate the reference voltage.

The controller 150 controls various operations of the display device 100. The controller 150 receives input image data IMG and a control signal CTRL from the outside. The controller 150 may provide the gate control signal GCS, the data control signal DCS, and the voltage control signal VCS in response to the control signal CTRL.

The controller 150 may convert the input image data IMG to be suitable for the display device 100 or the display unit 110, and may output the image data DATA. In one or more embodiments, the controller 150 may output the image data DATA by arranging the input image data IMG to be suitable the sub-pixels SP in row units.

Two or more components among the data driver 130, the voltage generator 140, and the controller 150 may be mounted in one integrated circuit. As shown in FIG. 1, the data driver 130, the voltage generator 140, and the controller 150 may be included in a driver integrated circuit (DIC). In this case, the data driver 130, the voltage generator 140, and the controller 150 may be functionally distinct components within the driver integrated circuit (DIC). In one or more other embodiments, at least one among the data driver 130, the voltage generator 140, and the controller 150 may be provided as a component separate from the driver integrated circuit (DIC).

The display device 100 may include at least one temperature sensor 160. The temperature sensor 160 is configured to sense an ambient temperature and generate temperature data TEP indicative of a sensed temperature. In one or more embodiments, the temperature sensor 160 may be located adjacent to the display unit 110 and/or the driver integrated circuit DIC.

The controller 150 may control various operations of the display device 100 in response to the temperature data TEP. In one or more embodiments, the controller 150 may adjust luminance of an image output from the display unit 110 in response to the temperature data TEP. For example, controller 150 may adjust the data signals and the first and second power voltages VDD and VSS by controlling components such as the data driver 130 and/or the voltage generator 140.

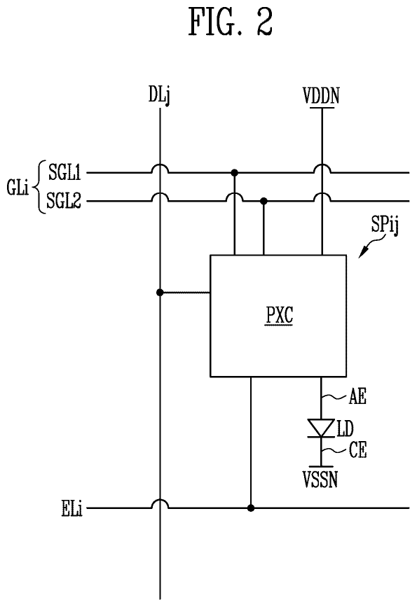

FIG. 2 is a block diagram illustrating one or more embodiments of a sub-pixel included in the display device of FIG. 1. In FIG. 2, among the sub-pixels SP in FIG. 1, a sub-pixel SPij arranged in an i-th row (i is an integer greater than or equal to 1 and less than or equal to m) and a j-th column (j is an integer greater than or equal to 1, and less than or equal to n) is shown as an example.

Referring to FIG. 2, the sub-pixel SPij may include a sub-pixel circuit PXC and a light-emitting element LD.

The light-emitting element LD is connected between a first power voltage node VDDN and a second power voltage node VSSN. The first power voltage node VDDN is a node that transmits the first power voltage VDD of FIG. 1, and the second power voltage node VSSN is a node that transmits the second power voltage VSS (or a cathode voltage) of FIG. 1.

An anode electrode AE of the light-emitting element LD may be connected to the first power voltage node VDDN through the sub-pixel circuit PXC, and a cathode electrode CE of the light-emitting element LD may be coupled to the second power voltage node VSSN. For example, the anode electrode AE of the light-emitting element LD may be connected to the first power voltage node VDDN through one or more transistors included in the sub-pixel circuit PXC.

The sub-pixel circuit PXC may be connected to an i-th gate line GLi among the first to m-th gate lines GL1 to GLm of FIG. 1, an i-th light emission control line ELi among the first to n-th light-emitting control lines EL1 to ELm of FIG. 1 and a j-th data line DLj among the first to N-th data lines DL1 to DLn of FIG. 1. The sub-pixel circuit PXC is configured to control the light-emitting element LD according to signals received through these signal lines.

The sub-pixel circuit PXC may operate in response to a gate signal received through the i-th gate line GLi. The i-th gate line GLi may include one or more sub-gate lines. In one or more embodiments, as shown in FIG. 2, the i-th gate line GLi may include first and second sub-gate lines SGL1 and SGL2. The sub-pixel circuit PXC may operate in response to gate signals received via the first and second sub-gate lines SGL1 and SGL2. As such, in case that the i-th gate line GLi includes two or more sub-gate lines, the sub-pixel circuit PXC may operate in response to gate signals received through the corresponding sub-gate lines.

The sub-pixel circuit PXC may operate in response to a light emission control signal received through the i-th light emission control line ELi. In one or more embodiments, the i-th emission control line ELi may include one or more sub-emission control lines. In case that the i-th light emission control line ELi includes two or more sub light emission control lines, the sub-pixel circuit PXC may operate in response to light emission control signals received through the corresponding sub light emission control line.

The sub-pixel circuit PXC may receive a data signal through the j-th data line DLj. The sub-pixel circuit PXC may store a voltage corresponding to the data signal in response to at least one of the gate signals received through the first and second sub-gate lines SGL1 and SGL2. In response to the light emission control signal received through the i-th light emission control line ELi, the sub-pixel circuit PXC may control a current flowing from the first power voltage node VDDN to the second power voltage node VSSN through the light-emitting element LD according to the stored voltage. Accordingly, the light-emitting element LD may generate light having a luminance corresponding to the data signal.

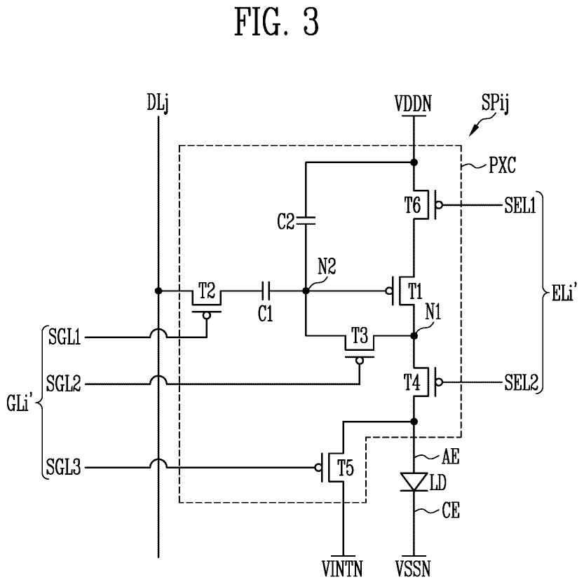

FIG. 3 is a circuit diagram illustrating one or more embodiments of the sub-pixel of FIG. 2.

Referring to FIG. 3, the sub-pixel SPij may include a sub-pixel circuit PXC and a light-emitting element LD.

The sub-pixel circuit PXC may be connected to the i-th gate line GLi′, the i-th light emission control line ELi′, and the j-th data line DLj. Compared with the i-th gate lines GLi of FIG. 2, the i-th gate line GLi′ may further include a third sub-gate line SGL3. Compared with the i-th emission control line ELi of FIG. 2, the i-th light emission control line ELi′ may include a first sub-light emission control line SEL1 and a second sub-light emission controls line SEL2.

The sub-pixel circuit PXC may include first to sixth transistors T1 to T6, and first and second capacitors C1 and C2.

The first transistor T1 is connected between the first power voltage node VDDN and the first node N1. A gate (or gate electrode) of the first transistor T1 is connected to the second node N2, so that the first transistor T1 may be turned on according to the voltage level of the second node N2. The first transistor T1 may be referred to as a driving transistor.

The second transistor T2 is connected between the j-th data line DLj and the second node N2. A gate of the second transistor T2 is connected to the first sub-gate line SGL1, so that the second transistor T2 may be turned on in response to the gate signal of the first sub-gate line SGL1. The second transistor T2 may be referred to as a switching transistor.

The third transistor T3 is connected between the first node N1 and the second node N2. A gate of the third transistor T3 is connected to the second sub-gate line SGL2, so that the third transistor T3 may be turned on in response to the gate signal of the second sub-gate line SGL2.

The fourth transistor T4 is connected between the first node N1 and an anode electrode AE of the light-emitting element LD. A gate of the fourth transistor T4 is connected to the second sub-light emission control line SEL2, so that the fourth transistor T4 may be turned on in response to the light emission control signal of the second sub-emitting control line SEL2.

The fifth transistor T5 is connected between the anode electrode AE of the light-emitting element LD and an initialization voltage node VINTN. The initialization voltage node VINTN is configured to deliver an initialization voltage. In one or more embodiments, the initialization voltage may be provided by the voltage generator 140 of FIG. 1. In one or more other embodiments, the initialization voltage may be provided by an external device of the display device 100. A gate of the fifth transistor T5 is connected to the third sub-gate line SGL3, so that the fifth transistor T5 may be turned on in response to the gate signal of the third sub-gate line SGL3.

The sixth transistor T6 is connected between the first power voltage node VDDN and the first transistor T1. A gate of the sixth transistor T6 is connected to the first sub-light emission control line SEL1, so that the sixth transistor T6 may be turned on in response to the light emission control signal of the first sub-light emission control line SEL1.

The first capacitor C1 is connected between the second transistor T2 and the second node N2. The second capacitor C2 is connected between the first power voltage node VDDN and the second node N2.

As such, the sub-pixel circuit PXC may include first to sixth transistors T1 to T6, and first and second capacitors C1 and C2. However, embodiments are not limited thereto. The sub-pixel circuit PXC may be implemented in any one of various forms of circuits including transistors and one or more capacitors. For example, the sub-pixel circuit PXC may include two transistors and one capacitor. According to embodiments of the sub-pixel circuit PXC, the number of sub-gate lines included in the i-th gate line GLi′ and the number of sub light emission control lines included in the i-th light emission control line ELi′ may vary.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

In one or more embodiments, the first to sixth transistors T1 to T6 may include an amorphous silicon semiconductor, a monocrystalline silicon, a polycrystalline silicon semiconductor, an oxide semiconductor, or the like.

The light-emitting element LD may include the anode electrode AE, a cathode electrode CE, and a light-emitting layer. The light-emitting layer may be located between the anode electrode AE and the cathode electrode CE. After the data signal transmitted through the j-th data line DLj is reflected in the voltage of the second node N2, the fourth and sixth transistors T4 and T6 may be turned on when the light emission control signals of the first and second sub-light emission control lines SEL1 and SEL2 are enabled to a low level. The first transistor T1 may be turned on according to the voltage of the second node N2, and thus a current may flow from the first power voltage node VDDN to the second power voltage node VSSN. The light-emitting element LD may emit light according to the amount of current flowing through the light-emitting element LD.

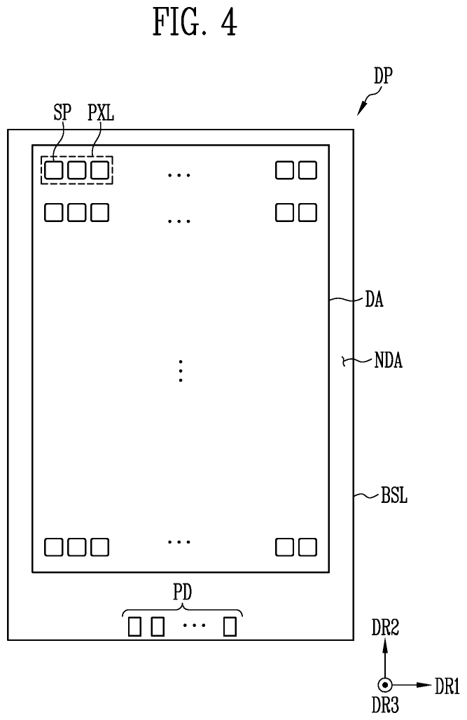

FIG. 4 is a plan view illustrating one or more embodiments of a display unit included in the display device of FIG. 1.

Referring to FIG. 4, a display panel DP, which is one or more embodiments of the display unit 110 of FIG. 1, may include a display area DA and a non-display area NDA. The display panel DP displays an image through the display area DA. The non-display area NDA is located around the display area DA (e.g. in plan view).

The display panel DP may include a base layer BSL, sub-pixels SP, and pads PD.

In case that the display panel DP is used as a display screen of a head mounted display (HMD), a virtual reality (VR) device, a mixed reality (MR) device, an augmented reality (AR) device, or the like, the display panel DP may be positioned very close to the user's eyes. In this case, sub-pixels SP having a relatively high integration are required. To increase the integration of the sub-pixels SP, the base layer BSL may be provided as a silicon substrate. The sub-pixels SP and/or the display panel DP may be formed on the base layer BSL, which is a silicon substrate, but is not necessarily limited thereto.

The sub-pixels SP are located in the display area DA on the base layer BSL. The sub-pixels SP may be arranged in a matrix form along a first direction DR1, and along a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ form (PENTILE™ being a registered trademark of Samsung Display Co., Ltd., Republic of Korea). The first direction DR1 may be a row direction, and the second direction DR2 may be a column direction. Two or more sub-pixels of the sub-pixels SP may constitute one pixel PXL.

A component for controlling the sub-pixels SP may be located in the non-display area NDA on the base layer BSL. For example, wirings connected to the sub-pixels SP such as the first to m-th gate lines GL1 to GLm and the first to n-th data lines DL1 to DLn of FIG. 1 may be located in the non-display area NDA.

At least one of the gate driver 120, the data driver 130, the voltage generator 140, the controller 150, or the temperature sensor 160 of FIG. 1 may be integrated in the non-display area NDA of the display panel DP. In one or more embodiments, the gate driver 120 of FIG. 1 may be mounted on the display panel DP, and may be located in the non-display area NDA. In one or more other embodiments, the gate driver 120 may be implemented as an integrated circuit separate from the display panel DP. In one or more embodiments, the temperature sensor 160 may be located in the non-display area NDA to sense the temperature of the display panel DP.

The pads PD are located in the non-display area NDA on the base layer BSL. The pads PD may be electrically connected to the sub-pixels SP through wirings. For example, the pads PD may be connected to the sub-pixels SP through the first to n-th data lines DL1 to DLn of FIG. 1.

The pads PD may interface the display panel DP to other components of the display device 100 (see FIG. 1). In one or more embodiments, voltages and signals required for operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

In one or more embodiments, the display area DA may have various shapes. The display area DA may have the shape of a closed loop comprising straight and/or curved sides. For example, the display area DA may have shapes, such as a polygon, a circle, a semicircle, and an ellipse.

In one or more embodiments, the display panel DP may have a flat display surface. In one or more other embodiments, the display panel DP may have an at least partially rounded display surface. In one or more embodiments, the display panel DP may be bendable, foldable, or rollable. In such cases, the display panel DP and/or the base layer BSL may include materials having a flexible property.

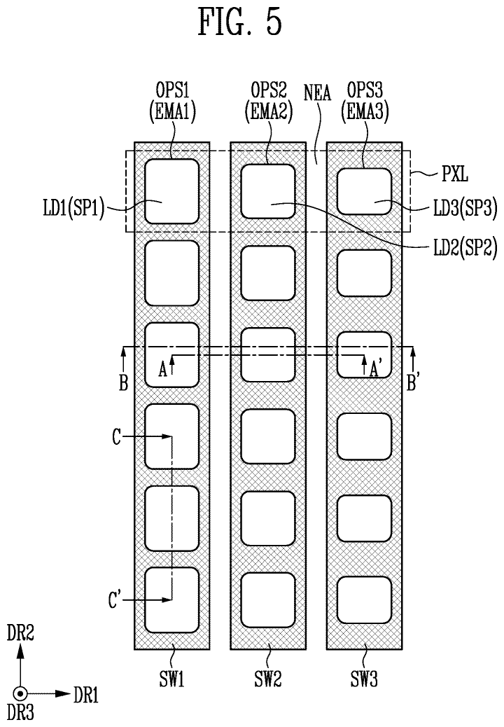

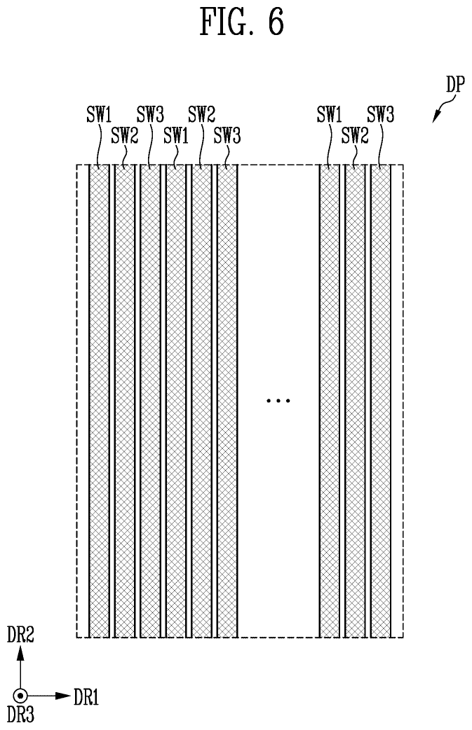

FIGS. 5 and 6 are plan views illustrating one or more embodiments of the display panel of FIG. 4. In FIG. 5, first to third sub-pixels SP1 to SP3 and first to third partition walls SW1 to SW3 are shown in a part of the display panel DP, and in FIG. 6, first to third partition wall SW1 to SW3 in the display panel DP are shown.

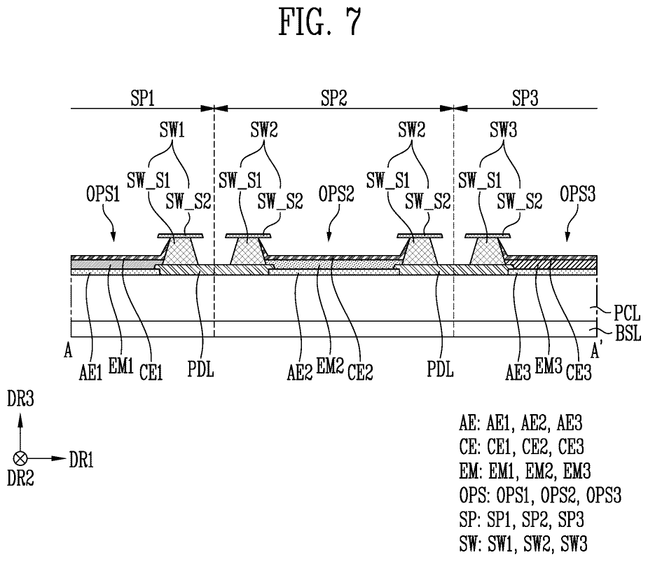

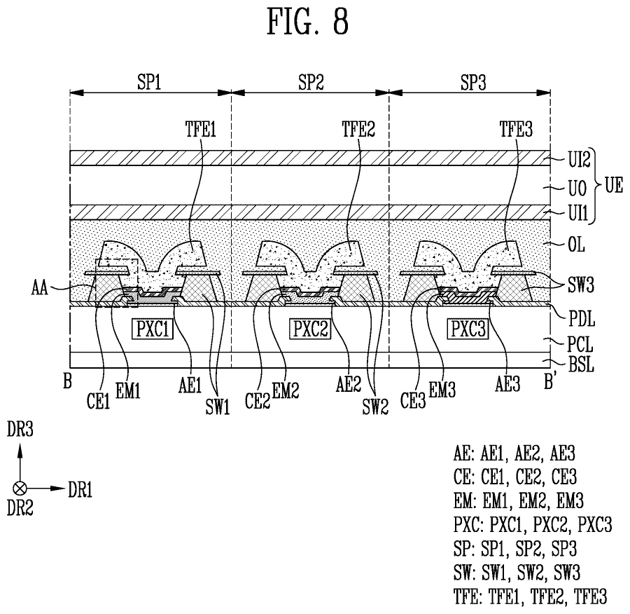

Referring to FIG. 5, the first partition wall SW1 (or a first electrode) includes first partition wall openings OPS1 (or first openings), and the first light-emitting element LD1 of the first sub-pixel SP1 may be located in each of the first partition wall openings OPS1. The first light-emitting element LD1 may be located in each of the first partition wall openings OPS1, and the first light-emitting elements LD1 may correspond to the first partition wall opening OPS1 (e.g., a one-to-one correspondence). For example, the first partition wall SW1 may extend in the second direction DR2, and the first partition wall openings OPS1 may be arranged along the second direction DR2. In a plan view, the first partition wall SW1 may surround only the first light-emitting element LD1. The first light-emitting element LD1 may emit light in a first color, for example, blue. The cathode electrode of the first light-emitting element LD1 may be electrically connected to the first partition wall SW1 (see FIGS. 7 and 8). A voltage (e.g., the second power voltage VSS of FIG. 1 applied to the second power voltage node VSSN of FIGS. 2 and 3) may be applied to the cathode electrode of the first light-emitting element LD1 through the first partition wall SW1.

The second partition wall SW2 (or a second electrode) includes second partition wall openings OPS2 (or second openings), and the second light-emitting element LD2 of the second sub-pixel SP2 may be located in each of the second partition wall openings OPS2. The second light-emitting element LD2 may be located in each of the second partition wall openings OPS2, and the second light-emitting elements LD2 may correspond to the second partition wall opening OPS2 one-to-one. For example, the second partition wall SW2 may be spaced apart from the first partition wall SW1 in the first direction DR1 and separated from or electrically insulated (or disconnected) from the first partition walls SW1. No electrode may be located between the first partition wall SW1 and the second partition wall SW2, but the present disclosure is not limited thereto. The second partition wall SW2 may extend in the second direction DR2, and the second partition wall openings OPS2 may be arranged along the second direction DR2. In a plan view, the second partition wall SW2 may surround the second light-emitting element LD2. The second light-emitting element LD2 may emit light in a second color, for example, red. The cathode electrode of the second light-emitting element LD2 may be electrically connected to the second partition wall SW2 (see FIGS. 7 and 8). A voltage may be applied to the cathode electrode of the second light-emitting element LD2 through the second partition wall SW2.

The third partition wall SW3 (or a third electrode) includes third partition wall openings OPS3 (or third openings), and a third light-emitting element LD3 of the third sub-pixel SP3 may be located in each of the third partition wall openings OPS3. One third light-emitting element LD3 may be located in each of the third partition wall openings OPS3, and the third light-emitting elements LD3 may correspond to the third partition wall opening OPS3 one-to-one. For example, the third partition wall SW3 may be spaced apart from the second partition wall SW2 in the first direction DR1 and separated from or electrically insulated from the second partition walls SW2 (and the first partition wall SW1). No electrode may be located between the second partition wall SW2 and the third partition wall SW3, but the present disclosure is not limited thereto. The third partition wall SW3 extends in the second direction DR2, and the third partition wall openings OPS3 may be arranged along the second direction DR2. In a plan view, the third partition wall SW3 may surround the third light-emitting element LD3. The third light-emitting element LD3 may emit light in a third color, for example, green. The cathode electrode of the third light-emitting element LD3 may be electrically connected to the third partition wall SW3 (see FIGS. 7 and 8). A voltage may be applied to the cathode electrode of the third light-emitting element LD3 through the third partition wall SW3.

As shown in FIG. 6, the first partition wall SW1, the second partition wall SW2, and the third partition wall SW3 may be alternately and repeatedly arranged along the first direction DR1.

Corresponding to the arrangement of the first to third light-emitting elements LD1 to LD3, the first sub-pixel SP1, the second sub-pixel SP2, and the third sub-pixel SP3 may be sequentially arranged along the first direction DR1. Each of the first sub-pixel SP1, the second sub-pixel SP2, and the third sub-pixel SP3 may be repeatedly arranged along the second direction DR2. The first sub-pixel SP1, the second sub-pixel SP2, and the third sub-pixel SP3 may constitute one pixel PXL.

The first sub-pixel SP1 may include a first light emission area EMA1. The first light emission area EMA1 may be an area where light is emitted from the first light-emitting element LD1 (or the light-emitting layer) of the first sub-pixel SP1, and may correspond to the first partition wall opening OPS1 of the first partition wall SW1. The second sub-pixel SP2 may include a second light emission area EMA2. The second light emission area EMA2 may be an area where light is emitted from the second light-emitting element LD2 of the second sub-pixel SP2, and may correspond to the second partition wall opening OPS2 of the second partition wall SW2. The third sub-pixel SP3 may include a third light emission area EMA3. The third light emission area EMA3 may be an area where light is emitted from the third light-emitting element LD3 of the third sub-pixel SP3, and may correspond to the third partition wall opening OPS3 of the third partition wall SW3. The periphery of the first to third light emission areas EMA1 to EMA3 may be a non-light emission area NEA.

In one or more embodiments, different voltages (or voltages having different voltage levels) may be applied to the first partition wall SW1, the second partition wall SW2, and the third partition wall SW3. Each of the voltages may be the second power voltage VSS of FIG. 1 applied to the second power voltage node VSSN of FIGS. 2 and 3. For reference, driving voltages for the first to third light-emitting elements LD1 to LD3 to emit light may be respectively different from each other. For example, the driving voltage of the first light-emitting element LD1 may be about 3.5 V, the driving voltages of the second light-emitting element LD2 may be about 3.8 V, and the driving voltage of a third light-emitting element LD3 may be about 3.9 V. The voltages applied to the first to third partition walls SW1 to SW3 may be respectively different from each other according to the driving voltages of the first to third light-emitting elements LD1 to LD3. However, the present disclosure is not limited thereto. For example, a voltage applied to the second partition wall SW2 may be different from a voltage applied to the first partition wall SW1, and a voltage applied to a third partition wall SW3 may be the same as the voltage applied to a second partition wall SW2.

As described above, the first to third partition walls SW1 to SW3 may be separated from each other, and different voltages may be provided to the first to third light-emitting elements LD1 to LD3 through the first to third partition walls SW1 to SW3. Voltages may be provided more optimally to the first to third light-emitting elements LD1 to LD3, so that power consumption may be reduced or improved.

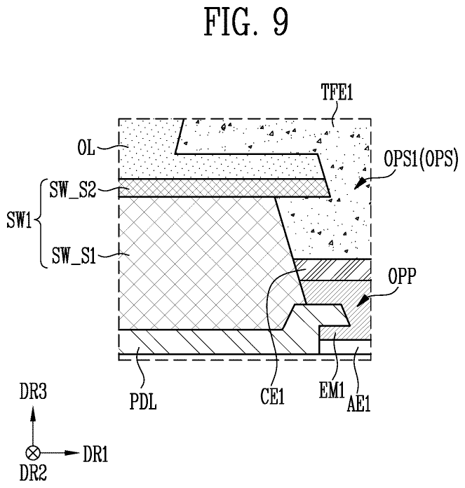

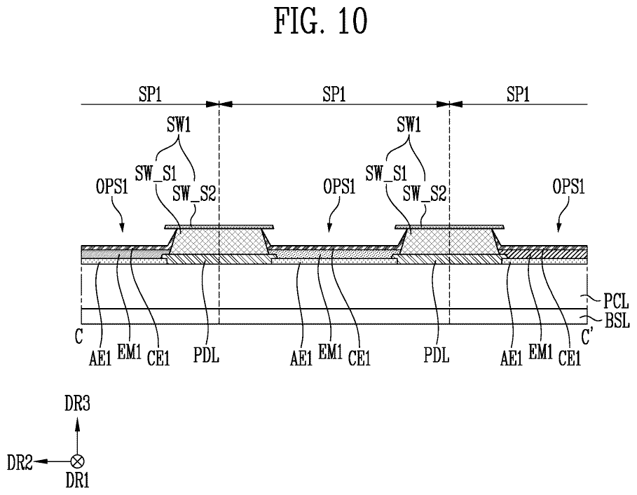

FIG. 7 is a cross-sectional view illustrating one or more embodiments of a display panel along the line A-A′ of FIG. 5. FIG. 8 is a cross-sectional view illustrating one or more embodiments of a display panel along the line B-B′ of FIG. 5. FIG. 9 is an enlarged view of an area AA of FIG. 8. FIG. 10 is a cross-sectional view illustrating one or more embodiments of a display panel along the line C-C′ of FIG. 5. FIGS. 7 and 10 show a configuration from the base layer BSL to the partition wall SW, and FIG. 8 further shows a configuration above the partition wall SW.

Referring to FIGS. 5 to 10, the base layer BSL may include a glass substrate. In one or more embodiments, the base layer BSL may include a polyimide (PI) substrate. In one or more embodiments, the base layer BSL may include a silicon wafer substrate formed using a semiconductor process. The base layer BSL may include a semiconductor material suitable for forming circuit elements, but is not necessarily limited to.

A pixel circuit layer PCL is located on the base layer BSL (as used herein, “located on” may mean “above”). The base layer BSL and/or the pixel circuit layer PCL may include insulating layers, and conductive patterns located between the insulating layers. The conductive patterns of the pixel circuit layer PCL may form the sub-pixel circuit PXC. The sub-pixel circuit PXC may be included in the corresponding sub-pixel SP. For example, the sub-pixel circuit PXC may include a first sub-pixel circuit PXC1 of the first sub-pixel SP1, a second sub-pixel circuit PXC2 of the second sub-pixel SP2, and a third sub-pixel circuit PXC3 of the third sub-pixel SP3.

Each of the first to third sub-pixel circuits PXC1 to PXC3 may include transistors and one or more capacitors. Each transistor may include a semiconductor portion including a source region, a drain region, and a channel region, and a gate electrode superimposed on the semiconductor portion. In one or more embodiments, in case that the base layer BSL is provided as a glass substrate or a PI substrate, a semiconductor portion and a gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in a third direction DR3 with an insulating layer interposed between the electrodes. In one or more embodiments, in case that the base layer BSL is provided as a silicon substrate, a semiconductor portion is included in the base layer BSL, and a gate electrode may be included in the pixel circuit layer PCL as a conductive pattern of the pixel circuit layer PCL, but is not necessarily limited thereto.

An anode electrode AE may be located on the pixel circuit layer PCL. The anode electrode AE may contact the sub-pixel circuit PXC of the pixel circuit layer PCL. The anode electrodes AE may include an opaque conductive material capable of reflecting light, but embodiments are not limited thereto.

A first anode electrode AE1 may be located in the first sub-pixel SP1. The first anode electrode AE1 may be electrically connected to the first sub-pixel circuit PXC1. A second anode electrode AE2 may be located in the second sub-pixel SP2. The second anode electrode AE2 may be electrically connected to the second sub-pixel circuit PXC2. A third anode electrode AE3 may be located in the third sub-pixel SP3. The third anode electrode AE3 may be electrically connected to the third sub-pixel circuit PXC3.

A pixel-defining layer PDL is located on the anode electrodes AE. The pixel-defining layer PDL may include a light-emitting opening OPP (see FIG. 9) exposing a portion of each of the anode electrodes AE. Light emission areas respectively corresponding to the first to third sub-pixels SP1 to SP3 may be defined by the light-emitting opening OPP of the pixel-defining layer PDL. Alternatively, it may be understood that the light emission areas respectively corresponding to the first to third sub-pixels SP1 to SP3 are defined by the anode electrodes AE.

In one or more embodiments, the pixel-defining layer PDL may include an inorganic material. For example, the pixel-defining layer PDL may include silicon oxide SiOₓ and silicon nitride SiNₓ. In one or more other embodiments, the pixel-defining layer PDL may include an organic material. However, the material of the pixel-defining layer PDL is not limited thereto.

A partition wall SW may be located on the pixel-defining layer PDL. The partition wall SW may be located at a boundary or between the first to third sub-pixels SP1 to SP3. The partition wall SW may include the first partition wall SW1, the second partition wall SW2, and the third partition wall SW3. The first partition wall SW1, the second partition wall SW2, and the third partition wall SW3 may be spaced apart from each other or separated from each other with respect to boundaries between the first to third sub-pixels SP1 to SP3. The partition wall SW is not separated between the sub-pixels SP that emit light of the same color. For example, as shown in FIG. 10, the first partition wall SW1 is not separated between the first sub-pixels SP1.

The partition wall SW may include a partition wall opening OPS overlapping the light-emitting opening OPP of the pixel-defining layer PDL in the third direction DR3. The first partition wall SW1 may include the first partition wall opening OPS1, the second partition wall SW2 may include the second partition wall opening OPS2, and the third partition wall SW3 may include the third partition wall opening OPS3. The partition wall opening OPS of the partition wall SW may expose the anode electrode AE together with the light-emitting opening OPP of the pixel-defining layer PDL.

The partition wall SW may include a first sub-partition wall SW_S1 and a second sub-partition wall SW_S2. The first sub-partition wall SW_S1 may be located on the pixel-defining layer PDL. The first sub-partition wall SW_S1 may be located directly on the pixel-defining layer PDL. The second sub-partition wall SW_S2 may be located on the first sub-partition wall SW_S1. The second sub-partition wall SW_S2 may be located directly on the first sub-partition walls SW_S1.

The partition wall SW may have an undercut shape in a cross-sectional view. For example, a width of the second sub-partition wall SW_S2 may be greater than a width of the first sub-partition walls SW_S1. For example, the second sub-partition wall SW_S2 may protrude from the first sub-partition walls SW_S1 in a planar direction defined by the first and second directions DR1 and DR2. For example, as shown in FIG. 9, the second sub-partition wall SW_S2 may form a tip protruding from the first sub-partition wall SW_S1. A thickness of the second sub-partition wall SW_S2 in the third direction DR3 may be smaller than a thickness of the first sub-partition walls SW_S1 in the third direction DR3, but is not necessarily limited thereto. In one or more embodiments, the second sub-partition wall SW_S2 may have a robust characteristic to an etching environment, as compared to the first sub-partition wall SW_S1. For example, the first sub-partition wall SW_S1 may include aluminum (Al), and the second sub-partition Wall SW_S2 may include titanium (Ti), but is not necessarily limited thereto. The tip of the second sub-partition wall SW_S2 may serve to separate a light-emitting layer EM and/or a cathode electrode CE, which will be described later.

In one or more embodiments, the first sub-partition wall SW_S1 and/or the second sub-partition wall SW_S2 may include a conductive material. In one or more embodiments, the first sub-partition wall SW_S1 and the second sub-partition wall SW_S2 may include different conductive materials. The first sub-partition wall SW_S1 and the second sub-partition wall SW_S2 may be electrically connected to the cathode electrode CE to transmit the second power voltage VSS to the cathode electrode CE.

The light-emitting layer EM may be located on the anode electrodes AE. The light-emitting layer EM may be located in the light-emitting opening OPP of the pixel-defining layer PDL, and in the partition wall opening OPS of the partition wall SW. The light-emitting layer EM may be located on the anode electrodes AE exposed by the light-emitting opening OPP and the partition wall opening OPS.

The light-emitting layer EM may include an intermediate layer configured to generate light, an electron transport layer configured to transport electrons, a hole transport layer configured to transmit holes, and the like.

The light-emitting layer EM may include a first light-emitting layer EM1 of the first sub-pixel SP1, a second light-emitting layer EM2 of the second sub-pixel SP2, and/or a third light-emitting layer EM3 of the third sub-pixel SP3. The first to third light-emitting layers EM1 to EM3 may emit light of different colors. For example, the first light-emitting layer EM1 may emit light in blue, the second light-emitting layer EM2 may emit light in red, and the third light-emitting layer EM3 may emit light in green, but the present disclosure is not necessarily limited thereto.

The first light-emitting layer EM1 may be located in the light-emitting opening OPP of the pixel-defining layer PDL of the first sub-pixel SP1 and the first partition wall opening OPS1 of the first partition wall SW1. The second light-emitting layer EM2 may be located in the light-emitting opening OPP of the pixel-defining layer PDL of the second sub-pixel SP2 and the second partition wall opening OPS2 of the second partition wall SW2. The third light-emitting layer EM3 may be located in the light-emitting opening OPP of the pixel-defining layer PDL of the third sub-pixel SP3 and the third partition wall opening OPS3 of the third partition wall SW3.

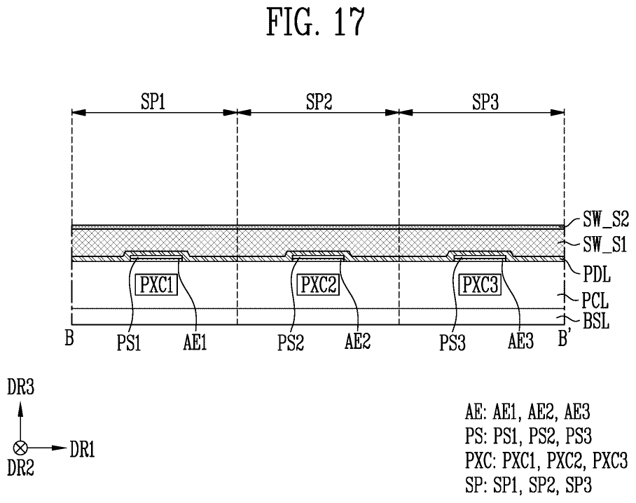

In one or more embodiments, the pixel-defining layer PDL (or an edge of the pixel-defining layer PDL) may be spaced apart from a top surface of the anode electrode AE in the third direction DR3, and the light-emitting layer EM may be filled between the pixel-defining layer DPL and the anode electrode AE. For example, as shown in FIG. 9, an edge of the pixel-defining layer PDL may be spaced apart from an upper surface of the first anode electrode AE1 in the third direction DR3. As will be described later with reference to FIG. 17, a sacrificial layer (or a protective layer) may be located between the anode electrode AE and the pixel-defining layer PDL to reduce or prevent damage to the anode electrode AE in a process of etching the pixel-defining layer PDL and/or the partition wall SW or the like. The pixel-defining layer PLD may be spaced apart from the upper surface of the anode electrode AE in the third direction DR3 while the sacrificial layer is removed in the process of forming the light-emitting openings OPP of the pixel-defining layers PDL.

A cathode electrode CE may be located on the light-emitting layer EM. The cathode electrode CE may be located in the partition wall opening OPS of the partition wall SW. The cathode electrode CE may be a thin metal layer having a thickness sufficient to transmit light emitted from the light-emitting layer EM. The cathode electrode CE may be formed of a metal material or a transparent conductive material to have a relatively thin thickness. In one or more embodiments, the cathode electrode CE may include at least one of various transparent conductive materials, including indium tin oxide, indium zinc oxide, indium tin zinc oxide, aluminum zinc oxide, gallium zinc oxide, zinc tin oxide, or gallium tin oxide. In one or more other embodiments, the cathode electrode CE may include at least one of silver (Ag), magnesium (Mg), or mixtures thereof. However, the material of the cathode electrode CE is not limited thereto.

The cathode electrode CE may include a first cathode electrode CE1 of the first sub-pixel SP1, a second cathode electrode CE2 of the second sub-pixel SP2 and/or a third cathode electrode CE3 of the third sub-pixel SP3. The first cathode electrode CE1 may be located on the first light-emitting layer EM1. The second cathode electrode CE2 may be located on the second light-emitting layer EM2. The third cathode electrode CE3 may be located on the third light-emitting layer EM3. The first cathode electrode CE1 may be located in the first partition wall opening OPS1 of the first partition wall SW1, and may contact the first partition wall SW1. The second cathode electrode CE2 may be located in the second partition wall opening OPS2 of the second partition wall SW2, and may contact the second partition wall SW2. The third cathode electrode CE3 may be located in the third partition wall opening OPS3 of the third partition wall SW3, and may contact the third partition wall SW3.

When holes injected from the anode electrode AE, and electrons injected from the cathode electrode CE, are transported into the intermediate layer of the light-emitting layer EM to form excitons, and when the excitons transition from an excited state to a ground state, light may be generated. The luminance of light may be determined according to the amount of current flowing through the intermediate layer. The wavelength range of the generated light may be determined according to the configuration of the intermediate layer.

The first anode electrode AE1, the first light-emitting layer EM1, and the first cathode electrode CE1 may constitute the first light-emitting element LD1 (see FIG. 5). The second anode electrode AE2, the second light-emitting layer EM2, and the second cathode electrode CE2 may constitute the second light-emitting element LD2 (see FIG. 5). The third anode electrode AE3, the third light-emitting layer EM3, and the third cathode electrode CE3 may constitute the third light-emitting element LD3 (see FIG. 5). Each of the first to third light-emitting elements LD1 to LD3 may be an organic light-emitting diode.

An encapsulation layer TFE is located on the cathode electrode CE and the partition wall SW. The encapsulation layer TFE may cover lower layers including the first to third light-emitting elements LD1 to LD3. The encapsulation layer TFE may be configured to reduce or prevent oxygen and/or moisture or the like from penetrating into the first to third light-emitting elements LD1 to LD3. In one or more embodiments, the encapsulation layer TFE may include an inorganic film or an organic film. For example, the inorganic film may include silicon nitride (SiNₓ), silicon oxide (SiOₓ), silicon oxynitride (SiOₓN_{y}), or the like. For example, the organic film may include an organic material, such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic film and the inorganic film of the encapsulation layer TFE are not limited thereto.

The encapsulation layer TFE may include a first encapsulation layer TFE1 of the first sub-pixel SP1, a second encapsulation layer TFE2 of the second sub-pixel SP2, and a third encapsulation layer TFE3 of the third sub-pixel SP3. The first encapsulation layer TFE1 may be located on the first cathode electrode CE1. The second encapsulation layer TFE2 may be located on the second cathode electrode CE2. The third encapsulation layer TFE3 may be located on the third cathode electrode CE3.

The first encapsulation layer TFE1 may be located in the first partition wall opening OPS1 of the first partition wall SW1. The second encapsulation layer TFE2 may be located in the second partition wall opening OPS2 of the second partition wall SW2. The third encapsulation layer TFE3 may be located in the third partition wall opening OPS3 of the third partition wall SW3.

In one or more embodiments, the first to third encapsulation layers TFE1 to TFE3 may be partially located on the partition wall SW (or the second sub-partition wall SW_S2). An edge of each of the first to third encapsulation layers TFE1 to TFE3 may be spaced apart from the partition wall SW (or the second sub-partition wall SW_S2). For example, an edge of each of the first to third encapsulation layers TFE1 to TFE3 may be spaced apart from an upper surface of the partition wall SW (or the second sub-partition wall SW_S2) in the third direction DR3. As shown in FIG. 9, an edge of the first encapsulation layer TFE1 may be spaced apart from an upper surface of the second sub-partition wall SW_S2 in the third direction DR3. If an external stress is applied, or if a panel strain occurs, such as bending of the display panel DP, the stress may be concentrated in a region where the edge of the encapsulating layer TFE and the lower layer are spaced apart, so that cracks may occur in the encapsulation layer TFE, and thus the encapsulation function may be lost. Accordingly, in the display device, the area in which the edge of the encapsulation layer TFE and the lower layer are spaced apart from each other is filled with the organic layer OL, thereby reducing or preventing the occurrence of cracks in the encapsulation layer TFE.

The organic layer OL may be located on and may cover the encapsulation layer TFE. The organic layer OL may fill between an edge of the encapsulation layer TFE and the partition wall SW (or the second sub-partition wall SW_S2). In one or more embodiments, the organic layer OL may completely fill between the edge of the encapsulation layer TFE and the partition wall SW (or the second sub-partition wall SW_S2). As shown in FIG. 9, the organic layer OL may completely fill between the edge of the first encapsulation layer TFE1 and the second sub-partition wall SW_S2. Accordingly, there may be no space, no cavity, or no void between the edge of the encapsulation layer TFE and the partition wall SW (or the second sub-partition wall SW_S2), but is not necessarily limited thereto. Because the organic layer OL is filled between the edge of the encapsulation layer TFE and the partition wall SW, even if the edge of the encapsulating layer TFE is spaced apart from the partition wall SW, it is possible to reduce or prevent the likelihood of cracks occurring in the encapsulating layers TFE.

The organic layer OL may also be filled between the first to third partition walls SW1 to SW3. The organic layer OL may contact the pixel-defining layer PDL between the first to third partition walls SW1 to SW3.

The organic layer OL may be formed of a photosensitive resin composition. The organic layer OL may be formed of a transparent photosensitive resin composition so that light emitted from the light-emitting layer EM may be transmitted. The organic layer OL may be formed of a low-temperature curable photosensitive resin composition to reduce or prevent damage to the light-emitting layer EM in the process of forming the organic layer OL. For example, the organic layer OL may be formed of a photosensitive resin composition capable of curing at a low temperature of about 70° C. to about 100° C., but is not necessarily limited thereto.

An upper encapsulation layer UE may be further located on the organic layer OL. The upper encapsulation layer UE may be configured to cover the lower layers to reduce or prevent oxygen and/or moisture or the like from penetrating the lower layers. The upper encapsulation layer UE may comprise a first upper inorganic layer UI1 (or a first upper encapsulation layer), an upper organic layer UO (or a second upper encapsulation layer) and/or a second upper inorganic layer UI2 (or a third upper encapsulation layer) sequentially stacked. However, the present disclosure is not necessarily limited thereto. In one or more embodiments, at least some of the first upper inorganic layer UI1, the upper organic layer UO, and the second upper inorganic layer UI2 may be omitted.

The first upper inorganic layer UI1 and the second upper inorganic layer UI2 may each include, but are not necessarily limited to, silicon nitride (SiNₓ), silicon oxide (SiOₓ), silicon oxynitride (SiOₓN_{y}), or the like. The upper organic layer UO may include an acrylic resin, an epoxy resin, a phenol resin, a polyamide resin, a polyimide resin, an unsaturated polyester resin, a polyphenylenether resin, a poly phenylenesulfide resin, benzocyclobutene (BCB), or the like, but is not necessarily limited to.

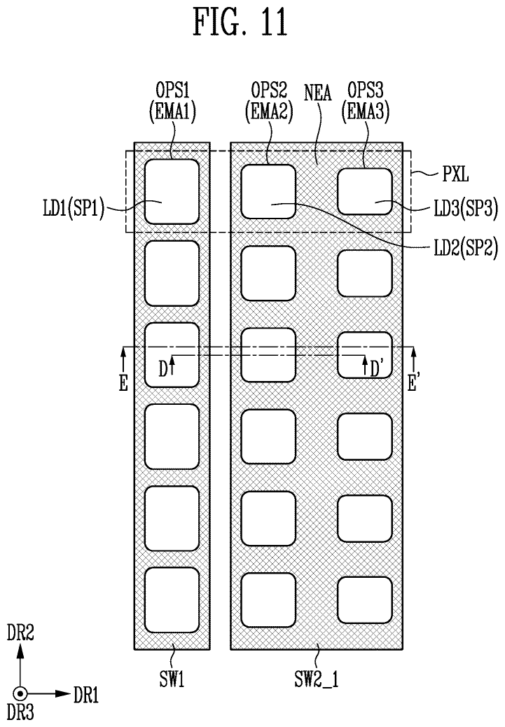

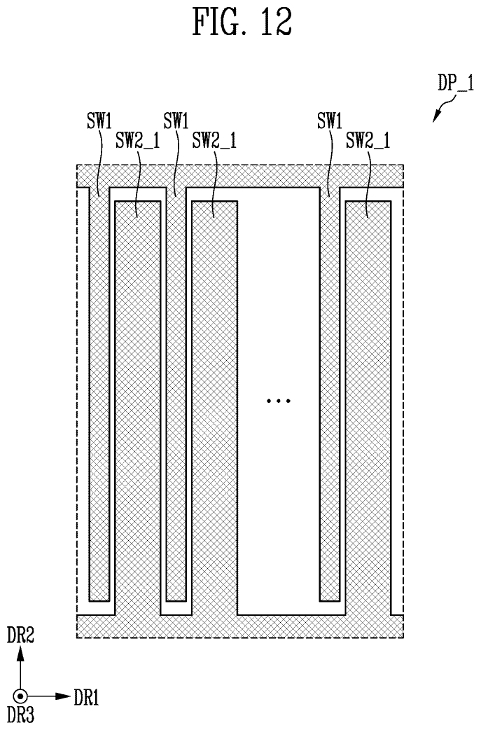

FIGS. 11 and 12 are plan views illustrating one or more other embodiments of the display panel of FIG. 4. In FIG. 11, first to third sub-pixels SP1 to SP3 and first and second partition walls SW1 and SW2_1 are illustrated in a part of the display panel DP, and in FIG. 12, first and second partition wall SW1 and SW 2_1 are illustrated in the display panel DP.

Referring to FIGS. 5, 6, 11, and 12, except for the second partition wall SW2_2, the embodiments of FIGS. 11 and 12 are substantially the same as or similar to those of FIGS. 5 and 6, and thus a redundant description will be omitted. The second partition wall SW2_1 of FIG. 11 may be similar to that in which the second and third partition walls SW2 and SW3 of FIG. 5 are integrally formed.

The second partition wall SW2_1 may further include third partition wall openings OPS3 (or third openings). The third light-emitting element LD3 of the third sub-pixel SP3 may be located in each of the third partition wall openings OPS3. The third partition wall openings OPS3 may be spaced apart from the second partition wall openings OPS2 in the first direction DR1, but are not limited thereto. In a plan view, the second partition wall SW2_1 may surround the second light-emitting element LD2 and the third light-emitting element LD3. The second light-emitting element LD2 may emit light in a second color, for example, red, and the third light-emitting element LD3 may emit light in a third color, for example green. The first light-emitting element LD1 may emit light in a first color, for example, blue.

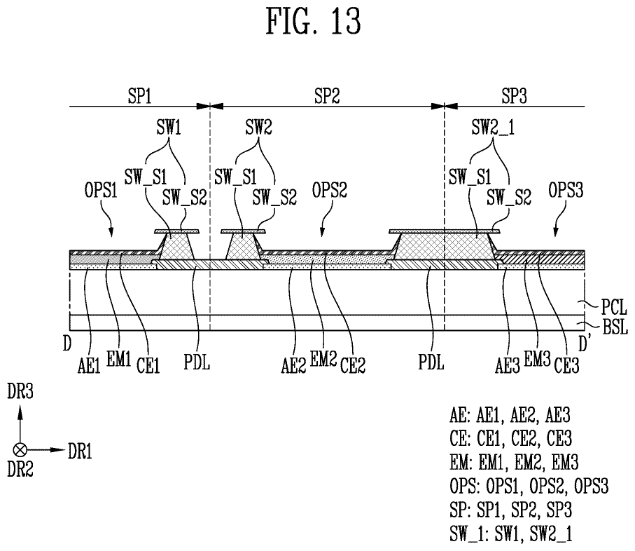

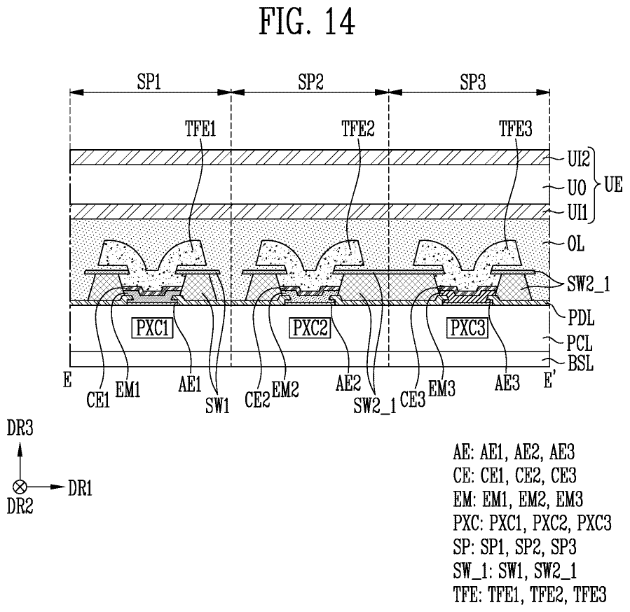

The cathode electrode of the third light-emitting element LD3 may be electrically connected to the second partition wall SW2_1 (see FIGS. 13 and 14). A voltage may be applied to the cathode electrode of the third light-emitting element LD3 through the second partition wall SW2_1.

As shown in FIG. 12, the first partition wall SW1 and the second partition wall SW2_1 may be alternately and repeatedly located along the first direction DR1. The first partition wall SW1 may be connected to another first partition wall SW1, at one end (e.g., an upper region) of the display panel DP_1 in the second direction DR2. Similarly, the second partition wall SW2_1 may be connected to another second partition wall SW2_1 at the other end (e.g., a lower region) of the display panel DP_1 in the second direction DR2.

In one or more embodiments, different voltages may be applied to the first partition wall SW1 and the second partition wall SW2_1. Each of the voltages may be the second power voltage VSS of FIG. 1 applied to the second power voltage node VSSN of FIGS. 2 and 3.

As described above, the first and second partition walls SW1 and SW2_1 are separated from each other, and different respective voltages may be provided to the first light-emitting element LD1 and to the second and third light-emitting elements LD2 and LD3 respectively through the first and second compartment walls SW1 and SW2_1.

FIG. 13 is a cross-sectional view illustrating one or more embodiments of a display panel along the line D-D′ of FIG. 11. FIG. 14 is a cross-sectional view illustrating one or more embodiments of a display panel along the line E-E′ of FIG. 11. A configuration from the base layer BSL to the partition wall SW_1 is shown in FIG. 13, and a configuration above the partition wall SW_ is further shown in FIG. 14.

Referring to FIGS. 7, 8, and 11 to 14, except for the second partition wall SW2_2, the embodiments of FIGS. 13 and 14 are substantially the same as or similar to those of FIGS. 7 and 8, and thus redundant descriptions will be omitted.

The partition wall SW_1 may be located on the pixel-defining layer PDL. The partition wall SW_1 may be located at a boundary or between the first to third sub-pixels SP1 to SP3. The partition wall SW_1 includes a first partition wall SW1 and a second partition wall SW2_1, and the first partition wall SW1 and the second partition wall SW2_1 may be spaced apart from each other or separated from each other with respect to a boundary between the first sub-pixel SP1 and the second sub-pixel SP2. The second partition wall SW2_1 (or the partition wall SW_1) is not separated between the second sub-pixel SP2 and the third sub-pixel SP3.

The partition wall SW_1 may include a partition wall opening OPS overlapping the light-emitting opening OPP of the pixel-defining layer PDL in the third direction DR3. The first partition wall SW1 may include a first partition wall opening OPS1, and the second partition wall SW2_1 may include a second partition wall opening OPS2 and a third partition wall opening OPS3. The partition wall opening OPS of the partition wall SW_1 may expose the anode electrode AE together with the light-emitting opening OPP of the pixel-defining layer PDL.

The first light-emitting layer EM1 may be located in the light-emitting opening OPP of the pixel-defining layer PDL of the first sub-pixel SP1, and in the first partition wall opening OPS1 of the first partition wall SW1. The second light-emitting layer EM2 may be located in the light-emitting opening OPP of the pixel-defining layer PDL of the second sub-pixel SP2, and in the second partition wall opening OPS2 of the second partition wall SW2_1. The third light-emitting layer EM3 may be located in the light-emitting opening OPP of the pixel-defining layer PDL of the third sub-pixel SP3, and in the third partition wall opening OPS3 of the second partition wall SW2_1.

A first cathode electrode CE1 may be located in the first partition wall opening OPS1 of the first partition wall SW1, and may contact the first partition wall SW1. A second cathode electrode CE2 may be located in the second partition wall opening OPS2 of the second partition wall SW2_1, and may contact the second partition wall SW2_1. A third cathode electrode CE3 may be located in the third partition wall opening OPS3 of the second partition wall SW2_1, and may be in contact with the second partition wall SW2_1.

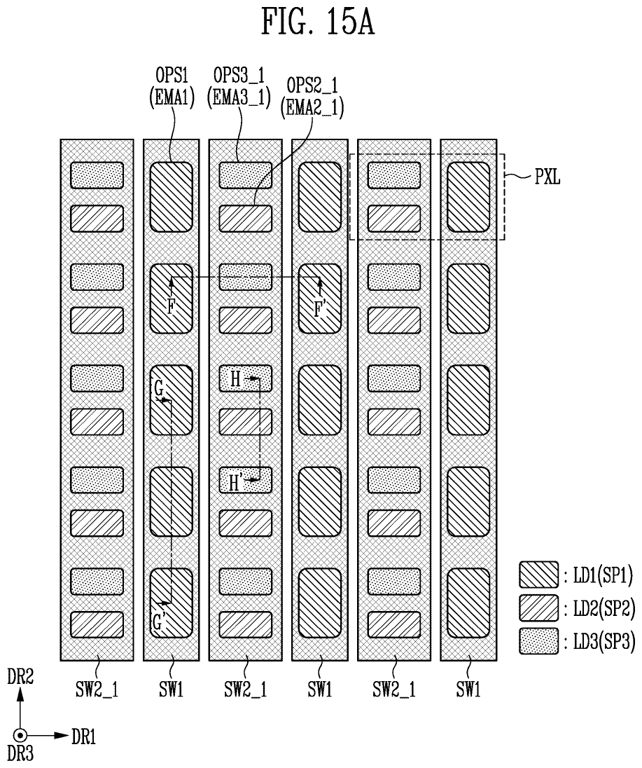

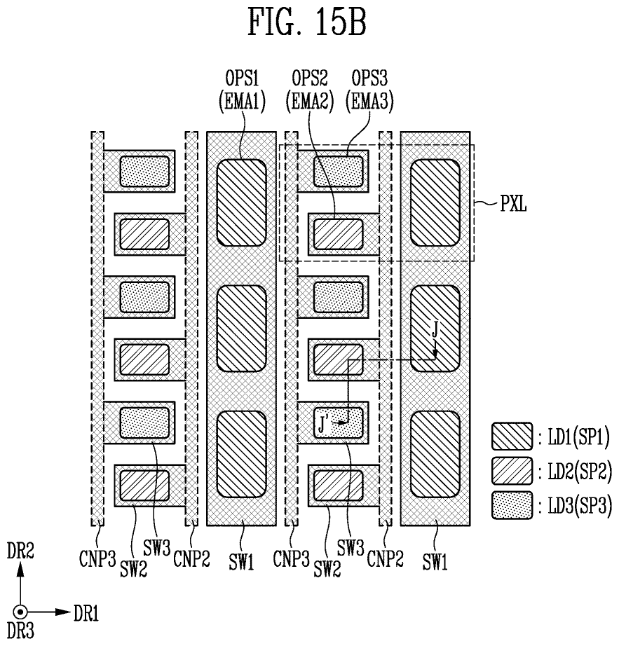

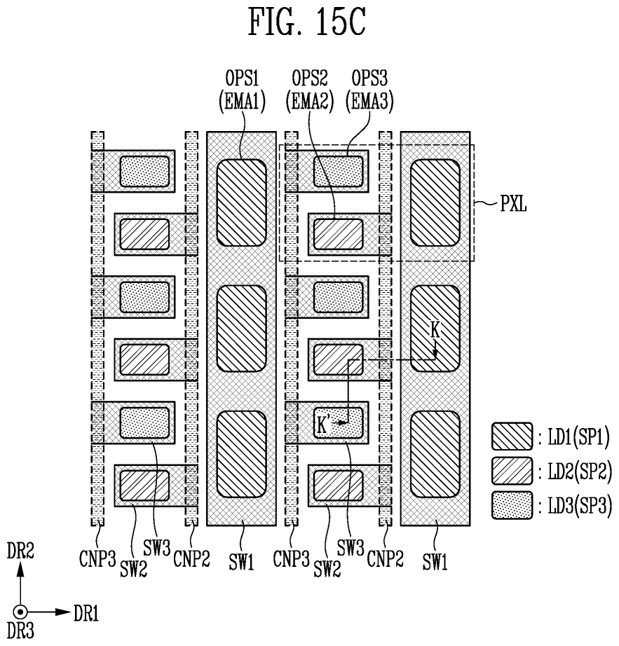

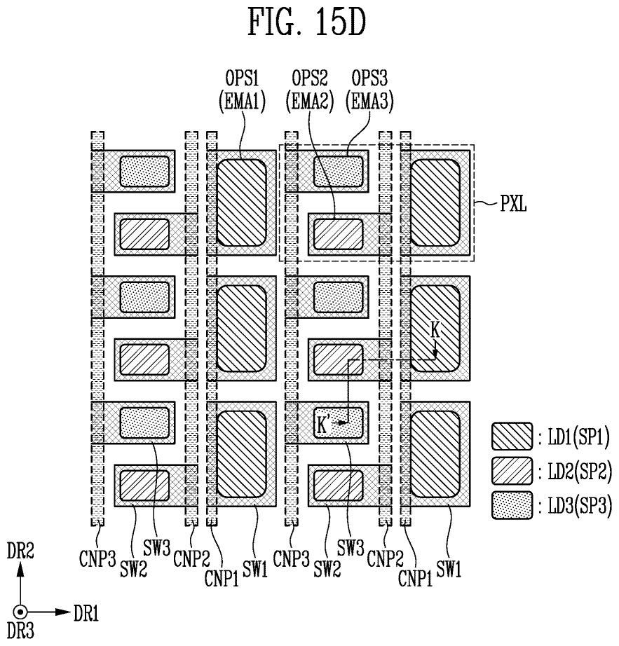

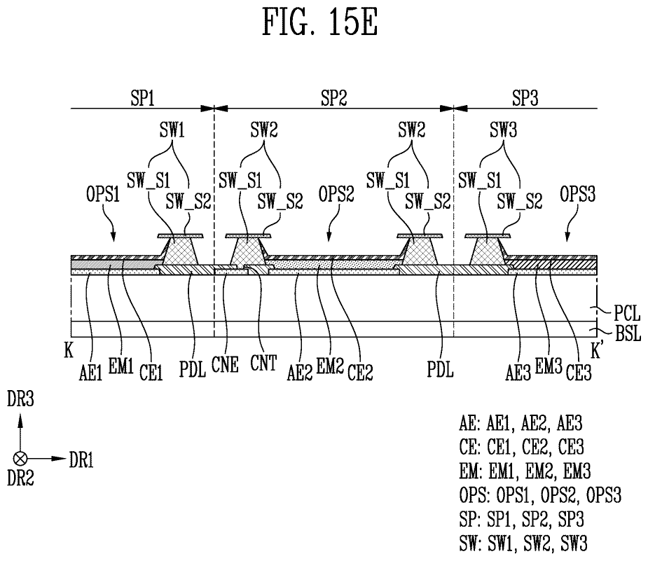

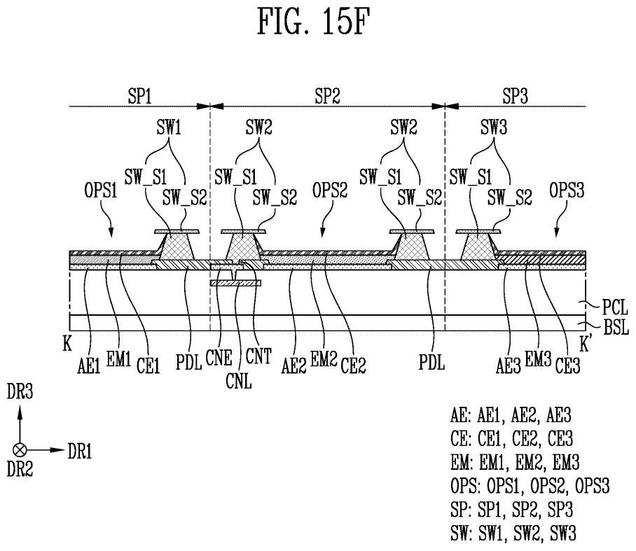

FIGS. 15A to 15D are plan views illustrating one or more other embodiments of the display panel of FIG. 4. FIGS. 15E and 15F are cross-sectional views illustrating one or more embodiments of a display panel along the line K-K′ of FIG. 15C.

Referring first to FIGS. 11, 12, and 15A, the one or more embodiments corresponding to FIG. 15A may be substantially the same as or similar to the one or more embodiments corresponding to FIGS. 11 and 12, except for arrangement of the second and third partition wall openings OPS2_1, OPS3_1. In addition, a cross-sectional view along the line F-F′ is substantially the same as or similar to the cross-sectional view of FIG. 7, and each of the cross-sectional views along the line G-G′ and the cross-sectional drawings along the line H-H′ may be substantially the same as or similar to the cross-sectional view of FIG. 10. Therefore, redundant descriptions will be omitted.

The first partition wall SW1 includes first partition wall openings OPS1, and the first light-emitting element LD1 of the first sub-pixel SP1 may be located in each of the first partition wall opening OPS1. The second partition wall SW2_1 may include second partition wall openings OPS2_1 and third partition wall openings OPS3_1, and the second light-emitting element LD2 of the second sub-pixel SP2 may be located in each of the second partition wall opening OPS2_1, and a third light-emitting element LDL3 of the third sub-pixel SP3 may be located at each of the third partition wall opening OPS3_1.

The first and second partition walls SW1 and SW2_1 may be separated from each other, and different voltages may be provided to the first light-emitting element LD1 and the second and third light-emitting elements LD2 and LD3 through the first and second partition wall SW1 and SW2_1.

As described with reference to FIG. 12, the first partition wall SW1 and the second partition wall SW2_1 may be alternately and repeatedly arranged along the first direction DR1. The first partition wall SW1 may be connected to another first partition wall SW1 at one end of the display panel DP_1 in the second direction DR2. Similarly, the second partition wall SW2_1 may be connected to another second partition wall SW1_1 at the other end of the display panel DP_1 in the second direction DR2.

The first partition wall openings OPS1 of the first partition wall SW1 may be arranged along the second direction DR2. The second and third partition wall openings OPS2_1 and OPS3_1 of the second partition wall SW2_1 may be arranged along the second direction DR2. As shown in FIG. 15A, the second partition wall opening OPS2_1 and the third partition wall opening OPS3_1 may be alternately and repeatedly arranged along the second direction DR2.

Corresponding to the arrangement of the second and third partition wall openings OPS2_1 and OPS3_1, the second sub-pixel SP2 and the third sub-pixel SP3 may be arranged in the second direction DR2. The first sub-pixel SP1 may be located in the first direction DR1 with respect to each of the second and third sub-pixels SP2 and SP3.

The second sub-pixel SP2 and the third sub-pixel SP3 may have an area that is smaller than that of the first sub-pixel SP1. Accordingly, a second emission area EMA2_1 and a third emission area EMA3_1 may have a smaller area than a first emission area EMA1. However, embodiments are not limited thereto.

Referring to FIGS. 15A and 15B, the one or more embodiments corresponding to FIG. 15B may be substantially the same as or similar to that of FIG. 15A, except for the second and third partitions SW2 and SW3. In addition, a cross-sectional view along the line J-J′ may be substantially the same as or similar to the cross-sectional view of FIG. 7. Therefore, redundant descriptions will be omitted.

The second partition wall SW2 may include second partition wall openings OPS2, and the second light-emitting element LD2 of the second sub-pixel SP2 may be located in each of the second partition wall openings OPS2. The third partition wall SW3 may include third partition wall openings OPS3, and the third light-emitting element LD3 of the third sub-pixel SP3 may be located in each of the third partition wall openings OPS3.

The first, second, and third partition walls SW1, SW2, and SW3 are separated from each other, and different voltages may be provided to the first, second and third light-emitting elements LD1, LD2, and LD3 through the first, second, and/or third partition walls SW1, SW2, and/or SW3.

The second partition wall SW2 may include portions or main patterns, each enclosing the second light-emitting element LD2, and the main patterns of the second partition wall SW2 may be interconnected through a second connection portion CNP2 (or a second connection pattern) extending in the second direction DR2.

Similarly, the third partition wall SW3 may include portions or main patterns, each enclosing the third light-emitting element LD3, and the main patterns of the third partition wall SW3 may be interconnected through a third connection portion CNP3 (or a third connection pattern) extending in the second direction DR2.

Corresponding to the arrangement of the second and third partition wall openings OPS2 and OPS3, main patterns of the second partition SW2 and main patterns of the third partition SW3 may be alternately and repeatedly located along the second direction DR2.

The second and third connection portions CNP2 and CNP3 may be formed through the same process as the second and third partition walls SW2 and SW3, but are not limited thereto.

In one or more embodiments, the second and third connections CNP2 and CNP3 may be located in a layer that is different from the main patterns of the second and third partition walls SW2 and SW3.

For example, as shown in FIG. 15C, the main patterns of the second and third partition walls SW2 and SW3 may be physically separated from each other. The second connecting portion CNP2 extends in the second direction DR2, and may overlap the main patterns of the second partition wall SW2.

For example, as shown in FIG. 15E, the second connection portion CNP2 may be a connection electrode CNE overlapping the second partition wall SW2 (or the main pattern). The connection electrode CNE may be positioned in the same layer as the anode electrodes AE through the same process as the anode electrodes AE. The second partition wall SW2 (or the main pattern) may be electrically connected to the connection electrode CNE through a contact hole CNT passing through the pixel-defining layer PDL. The connection electrode CNE may also be applied to the third connection portion CNP3.

For example, as shown in FIG. 15F, the second connection portion CNP2 may be a connection line CNL overlapping the second partition wall SW2 (or the main pattern). The connection line CNL may be located below the connection electrode CNE or may be included in the pixel circuit layer PCL. The second partition wall SW2 (or the main pattern) may be electrically connected to the connection line CNL through the connection electrode CNE. In one or more embodiments, the connection electrode CNE may be omitted, and the second partition wall SW2 (or the main pattern) may be directly connected to the connection line CNL.

In one or more embodiments, similar to the second and third connections CNP2 and CNP3, the first partition wall SW1 may also include the first connection CNP1.

For example, as shown in FIG. 15D, the first partition wall SW1 includes portions or main patterns that each surround the first light-emitting element LD1, and the main patterns of the first partition wall SW1 may be connected through a first connection portion CNP1 (or a first connection pattern) extending in the second direction DR2. The connection electrode CNE of FIG. 15E or the connection line CNL of FIG. 15F may be applied to the first connection portion CNP1.

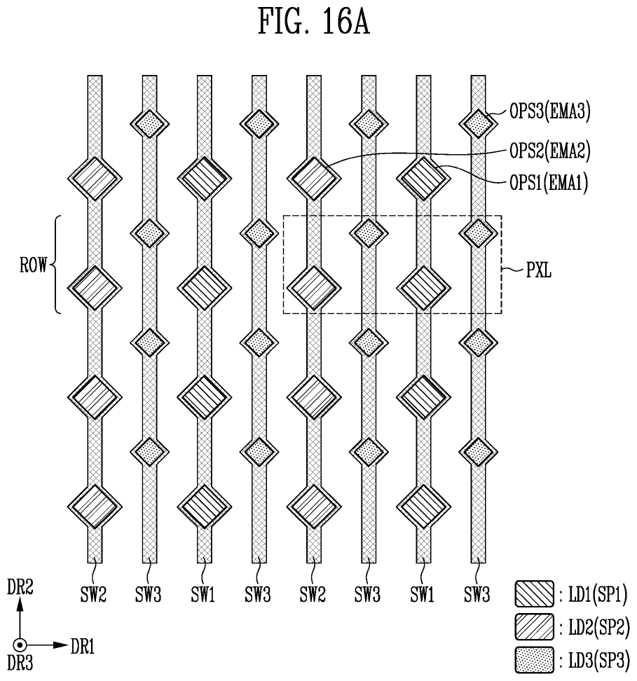

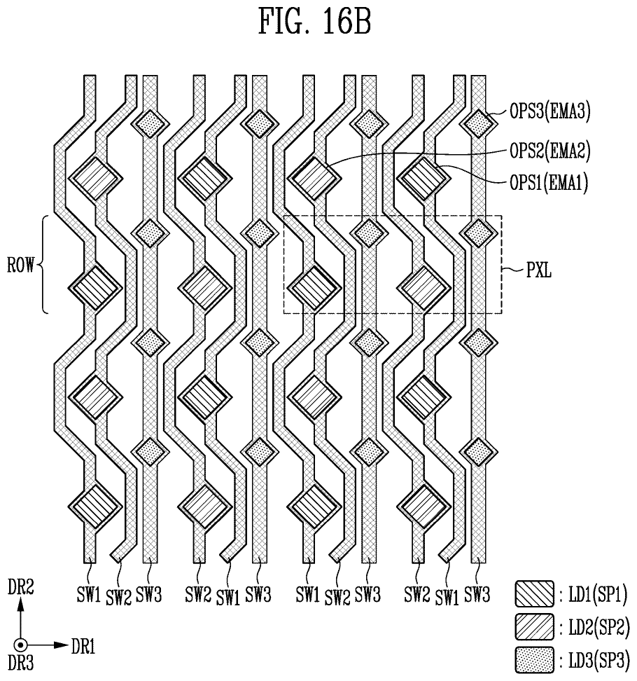

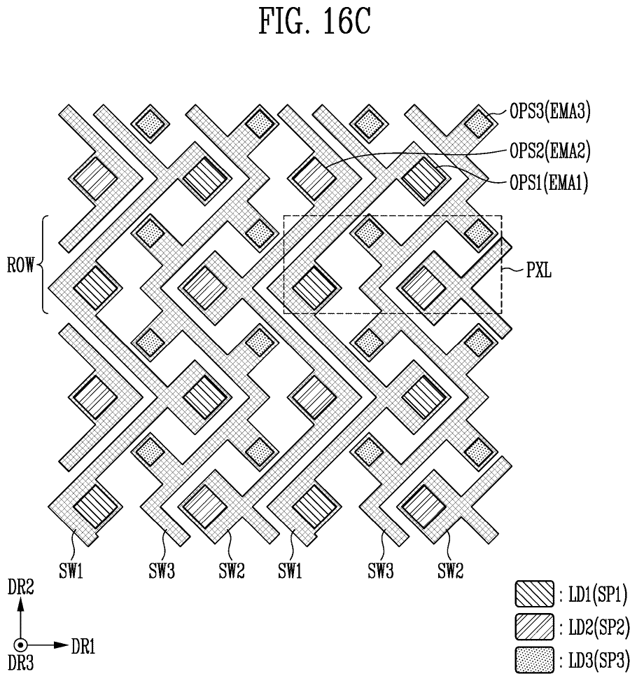

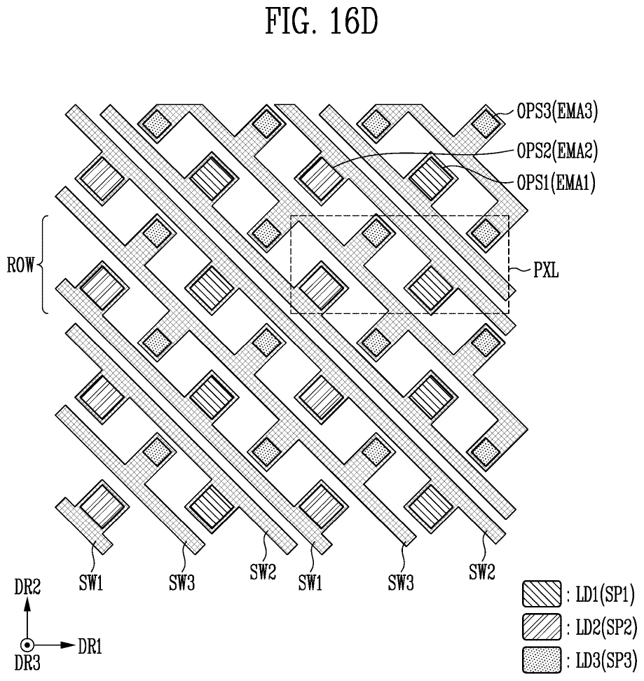

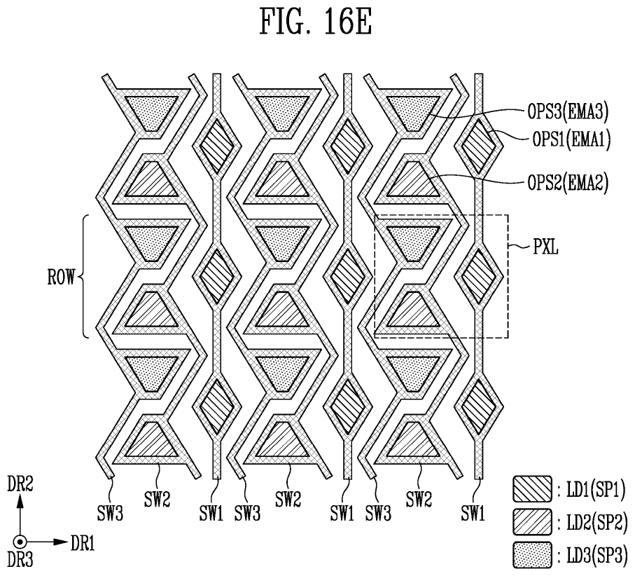

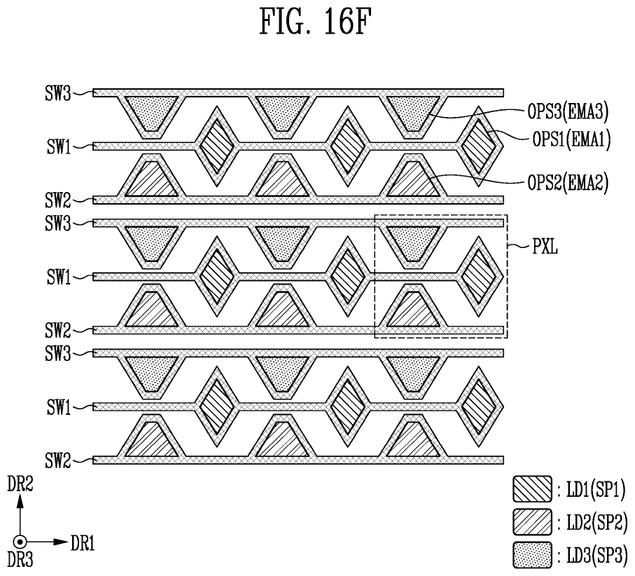

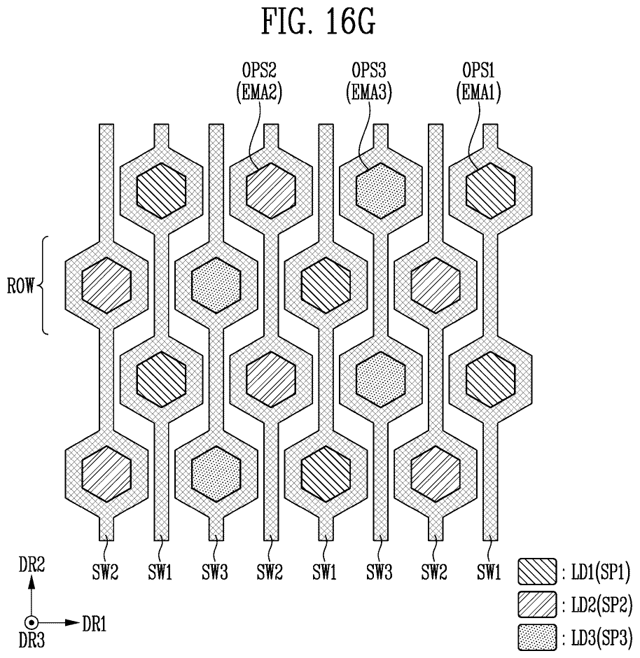

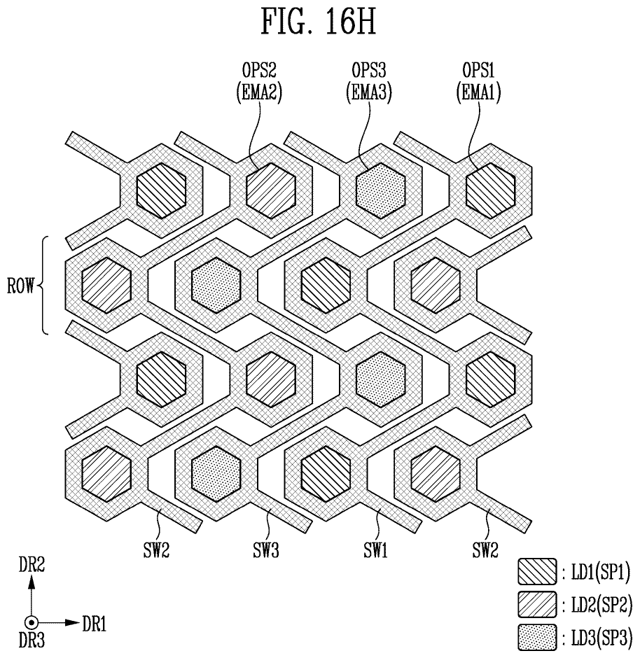

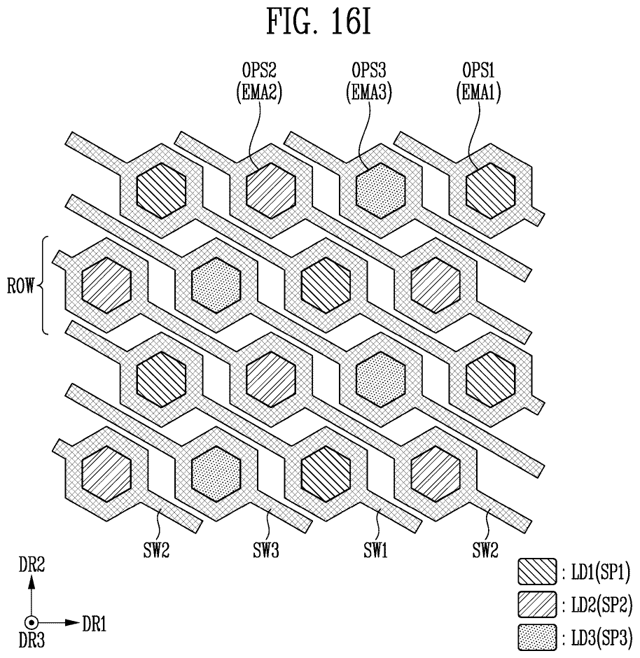

The arrangements of sub-pixels shown in FIGS. 15A to 15D are only an example, and embodiments are not limited thereto. Each pixel includes two or more sub-pixels, which may be arranged in various ways, and each of the sub-pixels may have various shapes, and each of light emission areas may also have various shapes. For example, a first partition wall SW1 may be arranged to connect sub-pixels emitting light in a first color, and a second partition wall SW2 may be arranged to connect sub-pixels emitted in a second color and not to connect the first partition wall SW1. An arrangement of partition walls SW1 to SW3 according to various arrangements of sub-pixels will be described with reference to FIGS. 16A to 16I.

FIGS. 16A to 16I are plan views illustrating one or more other embodiments of the display panel of FIG. 4. Because the relationship between the partition walls SW1 to SW3, the openings OPS1 to OPS3, and the light-emitting elements LD1 to LD3 has been described with reference to FIGS. 5 to 15F, redundant description will be omitted and shapes of the partition walls SW1-SW3 will be mainly described.

Referring to FIG. 16A, a first sub-pixel SP1, a third sub-pixel SP3, a second sub-pixel SP2, and a third sub-pixel SP3 may be repeatedly arranged along the first direction DR1 in a row ROW. For example, the sub-pixels SP1 to SP3 may be arranged in a PENTILE™ form (PENTILE™ being a registered trademark of Samsung Display Co., Ltd., Republic of Korea). The first sub-pixel SP1, the second sub-pixel SP2, and the two third sub-pixel SP3 may constitute a pixel PXL (or a unit pixel).

As only one type of light-emitting element is arranged in one column, the first partition wall SW1, the second partition wall SW2, and the third partition wall SW3 extend in the second direction DR2, and may be sequentially and repeatedly arranged along the first direction DR1.

Referring to FIGS. 16B to 16D, the sub-pixels SP1 to SP3 may be arranged in the form of a Diamond Pixel™ (Diamond Pixel™ being a registered trademark of Samsung Display Co., Ltd., Republic of Korea). The first light-emitting element LD1 and the second light-emitting element LD2 may be alternately arranged in a column.

In one or more embodiments, as shown in FIG. 16B, the first partition wall SW1 may extend generally in the second direction DR2, may surround the first light-emitting element LD1 in an odd-numbered row (or an even-numbered row), and may have a curved shape to circumvent the second light-emitting element LD2 (or a main pattern of the second partition wall SW2) in an even-numbered column (or an odd-numbered column). Similarly, the second partition wall SW2 generally extends in the second direction DR2 and surrounds the second light-emitting element LD2, and may have a curved shape to circumvent the first light-emitting element LD1 (or a main pattern of the first partition wall SW1).

In one or more embodiments, as shown in FIG. 16C, each of the first partition wall SW1 and the second partition wall SW2 may extend in a zigzag shape. For example, with respect to columns in which the first light-emitting elements LD1 are included, the first partition wall SW1 may extend in a first oblique direction from the first light-emitting element LD1 in a first row and a second column toward the first light-emitting element LD1 in a second row and a first column, may extend in a second oblique direction from the first light-emitting element LD1 of the second row and the first column toward the first light-emitting element LD1 in a third row and the second column, and may extend in the first oblique direction from the first light-emitting element LD1 in the third row and the second column toward the first light-emitting element LD1 in a fourth row and the first column. Similar to the first partition wall SW1, the second partition wall SW2 may also extend alternately in the first oblique direction and the second oblique direction. The third partition wall SW3 may also extend in a zigzag shape, but is not limited thereto. For example, the third partition wall SW3 may extend in the first direction DR1 so as to surround the two third light-emitting elements LD3 in the row ROW, and may extend in the second direction DR2 toward the third light-emitting element LD3 in another row ROW. That is, the third partition wall SW3 may extend alternately in the first direction DR1 and the second direction DR2.

In one or more embodiments, as shown in FIG. 16D, each of the partition walls SW1 to SW3 may extend generally in an oblique direction.

Referring to FIGS. 16E and 16F, the first light-emitting element LD1 may have a planar shape of a rhombus or diamond, and the second and third light-emitting elements LD2 and LD3 may have a triangular planar shape. In a row ROW, the second light-emitting element LD2 and the third light-emitting element LD3 may be arranged along the second direction DR2, and the first light-emitting element LD1 and the second and third light-emitting elements LD2 and LD3 may be repeatedly arranged along the first direction DR1.

As shown in FIG. 16E, each of the partition walls SW1 to SW3 may extend generally in the second direction DR2. Because the first light-emitting element LD1 and the second light-emitting element LD2 are alternately arranged in the row, the second partition wall SW2 may have a curved shape to circumvent the third light-emitting element LD3 (or the third partition wall SW3) while enclosing the second light-emitting element LD2. The third partition wall SW3 may have the same or similar shape as the second partition wall SW2.

As shown in FIG. 16F, each of the partition walls SW1 to SW3 may extend generally in the first direction DR1.

Referring to FIGS. 16G to 16I, each of the light-emitting elements LD1 to LD3 may have a hexagonal or circular planar shape. The light-emitting elements LD1 to LD3 may be arranged in a honeycomb shape.

As shown in FIG. 16G, the first partition wall SW1, the second partition wall SW2, and the third partition wall SW3 extend in the second direction DR2, and may be sequentially and repeatedly arranged along the first direction DR1.

As shown in FIG. 16H, each of the partition walls SW1 to SW3 may extend in a zigzag shape. For example, with respect to columns in which the second light-emitting elements LD2 are included, the second partition wall SW2 may extend in a first oblique direction from the second light-emitting element LD2 in a first row and a second column toward the second light-emitting element LD2 in a second row and a first column, may extend in a second oblique direction from the second light-emitting element LD2 in the second row and the first column toward the second light-emitting element LD2 in a third row and the second column, and may extend in the first oblique direction from the second light-emitting element LD2 in the third row and the second column toward the second light-emitting element LD2 in a fourth row and the first column. Similar to the second partition wall SW2, each of the first partition wall SW1 and the third partition wall SW3 may extend alternately in the first oblique direction and the second oblique direction.

As shown in FIG. 16I, each of the partition walls SW1 to SW3 may extend generally in an oblique direction.

A width of each of the partition walls SW1 to SW3 shown in FIGS. 16A to 16I and a distance between the partition walls SW1 to SW3 are only an example. Within a range in which the partition walls SW1 to SW3 are separated from each other, the width of the partition wall SW1 to SW3, and the distance between the partition walls SW1 to SW3 may be variously adjusted. For example, to make the distance between the partition wall SW1 to SW3 constant, the width of each of the partition walls SW1 to SW3 and the distance between the partition walls SW1 to SW3 may be set or a size of a main pattern (e.g., a portion surrounding the light-emitting element) and a width of a connection portion (e.g., a portion connecting the main patterns) of the partition wall SW1 to SW3 may be set. The connection electrode CNE of FIG. 15E or the connection line CNL of FIG. 15F may be applied to the connection portion.

FIGS. 17 to 24 are cross-sectional views of a process operation of a method of manufacturing a display device according to one or more embodiments. FIGS. 17 to 24 are cross-sectional views of each operation of a process for manufacturing the display panel of FIG. 8, and redundant descriptions will be omitted for convenience of description.

Referring to FIG. 17, a base layer BSL may be provided. A pixel circuit layer PCL may be formed on the base layer BSL, and anode electrodes AE may be formed on the pixel circuit layers PCL.

In one or more embodiments, a sacrificial layer (or a protective layer) PS may be located on the anode electrodes AE. The sacrificial layer PS may reduce or prevent the anode electrodes AE from being damaged in the process of etching a pixel-defining layer PDL and/or a partition wall SW. The sacrificial layer PS may include a first sacrificial layers PS1 formed on a first anode electrode AE1, a second sacrificial levels PS2 formed on a second anode electrode AE2, and a third sacrificial level PS3 formed on a third anode electrode AE3.

The pixel-defining layer PDL may be formed on the anode electrode AE and/or the sacrificial layer PS. The pixel-defining layer PDL may be entirely formed in the first to third sub-pixels SP1 to SP3.

A first sub-partition wall SW_S1 (or a first metal layer) may be formed on the pixel-defining layer PDL. The first sub-partition wall SW_S1 may be entirely formed in the first to third sub-pixels SP1 to SP3.

A second sub-partition wall SW_S2 (or a second metal layer) may be formed on the first sub-partition wall SW_S1. The second sub-partition wall SW_S2 may be entirely formed in the first to third sub-pixels SP1 to SP3.

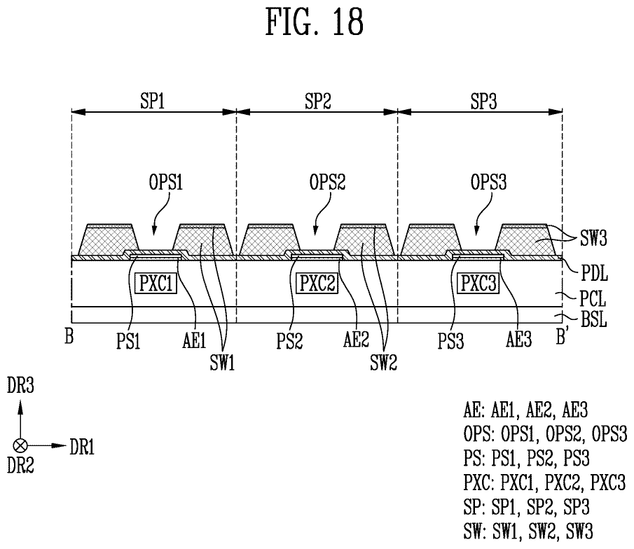

Referring to FIG. 18, first to third partition walls SW1 to SW3 and a partition wall opening OPS may be formed by primary etching (or dry etching) the first sub-partition wall SW_S1 and the second sub-partition wall SW_S2. The first partition wall SW1 may be formed in the first sub-pixel SP1, and the first partition wall opening OPS1 may be formed in the first partition wall SW1. The first partition wall opening OPS1 may overlap the first anode electrode AE1. The second partition wall SW2 may be formed in the second sub-pixel SP2, and the second partition wall opening OPS2 may be formed in the second partition wall SW2. The third partition wall SW3 may be formed in the third sub-pixel SP3, and the third partition wall opening OPS3 may be formed in the third partition wall SW3.

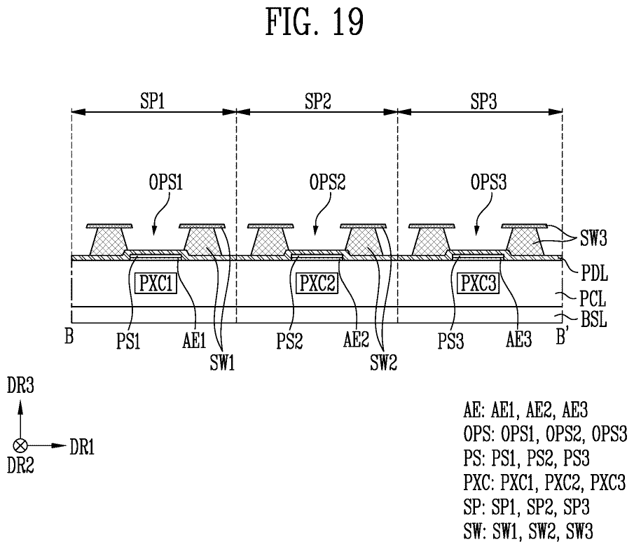

Referring to FIG. 19, a tip of the second sub-partition wall SW_S2 may be formed by secondary etching (or wet etching) the partition wall SW. In one or more embodiments, the secondary etching process may be performed in an environment in which an etching selectivity between the first sub-partition wall SW_S1 and the second sub-partition wall SW_S2 is greater. For example, the first sub-partition wall SW_S1 may be selectively etched as an etch rate of the first sub-partition wall SW_S1 for an etch solution is greater than an etch rate the second sub-partition wall SW_S2. Accordingly, a width of the second sub-partition wall SW_S2 may be formed to be greater than a width of the first sub-partition wall SW_S1, and the second sub-partition wall SW_S2 may form a tip protruding from the first sub-partition wall SW_S1. For example, the partition wall SW on which the secondary etching performed may have an undercut shape in a cross-sectional view.

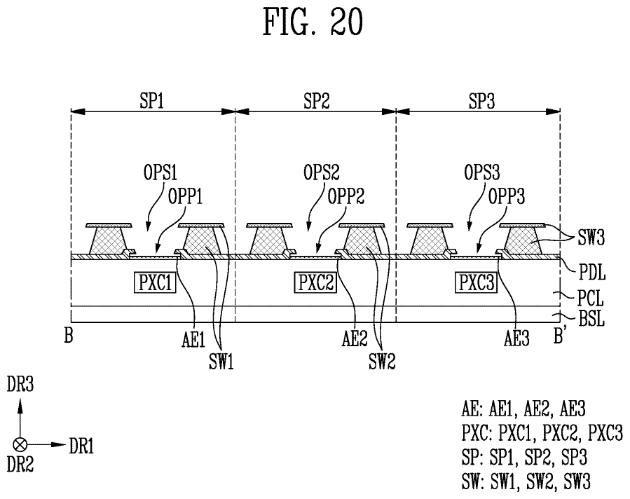

Referring to FIG. 20, the pixel-defining layer PDL may be etched to form first to third light-emitting openings OPP1 to OPP3. The first to third light-emitting openings OPP1 to OPP3 may be formed by etching the pixel-defining layer PDL exposed by the first to third partition wall openings OPS1 to OPS3. The first light-emitting opening OPP1 may overlap the first partition wall opening OPS1 in the third direction DR3. The second light-emitting opening OPP2 may overlap the second partition wall opening OPS2 in the third direction DR3. The third light-emitting opening OPP3 may overlap the third partition wall opening OPS3 in the third direction DR3.

The first to third light-emitting openings OPP1 to OPP3 may expose the anode electrode AE. The sacrificial layer PS may be removed in the operation of forming the first to third light-emitting openings OPP1 to OPP3, but is not necessarily limited thereto.

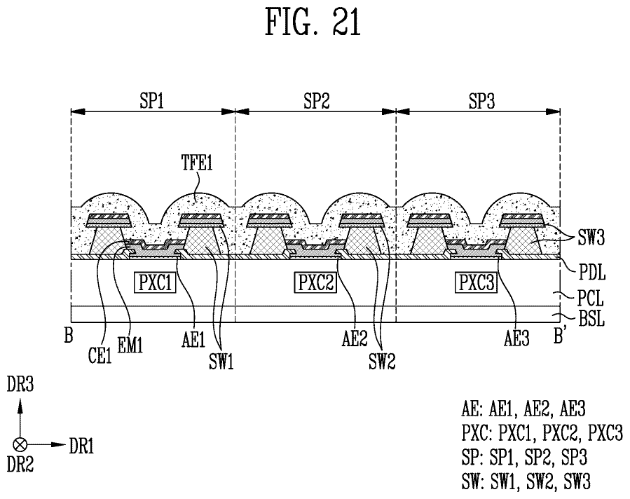

Referring to FIG. 21, a first light-emitting layer EM1, a first cathode electrode CE1, and a first encapsulation layer TFE1 may be formed on the first anode electrode AE1.

The first emission layer EM1 may be entirely formed in the first to third sub-pixels SP1 to SP3. The first light-emitting layer EM1 may be separated by a tip structure of the partition wall SW. Accordingly, one region of the first light-emitting layer EM1 may be formed in the first light-emitting opening OPP1 and/or the first partition wall opening OPS1. The one region of the first light-emitting layer EM1 may be formed on the first anode electrode AE1 exposed by the first light-emitting opening OPP1 and/or the first partition wall opening OPS1. Another region of the first light-emitting layer EM1 may be located in the second sub-pixel SP2 and the third sub-pixel SP3, but may be removed in a subsequent process.

The first cathode electrode CE1 may be formed on the first light-emitting layer EM1. The first cathode electrode CE1 may be formed entirely in the first to third sub-pixels SP1 to SP3. The first cathode electrode CE1 may be separated by the tip structure of the partition wall SW. Accordingly, one region of the first cathode electrode CE1 may be formed in the first partition wall opening OPS1. Another region of the first cathode electrode CE1 may be located in the second sub-pixel SP2 and the third sub-pixel SP3, but may be removed in a subsequent process.

The first encapsulation layer TFE1 may be formed on the first cathode electrode CE1. The first encapsulation layer TFE1 may be formed in the first partition wall opening OPS1. In one or more embodiments, the first encapsulation layer TFE1 may be entirely formed in the first to third sub-pixels SP1 to SP3.

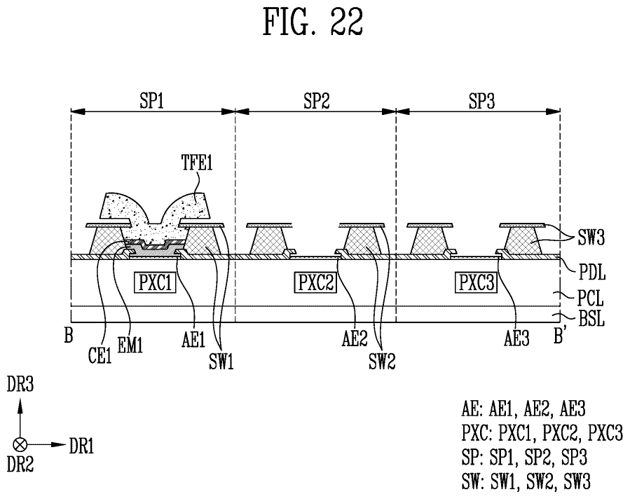

Referring to FIG. 22, the first encapsulation layer TFE1 may be etched. For example, a portion other than the first encapsulation layer TFE1 formed on the first partition wall SW1 may be etched and removed. In the process of etching the first encapsulation layer TFE1, layers formed in regions other than the first partition wall opening OPS1 (for example, another region of the first light-emitting layer EM1 and/or another region of the first cathode electrode CE1) may be removed together. Accordingly, a space may be formed between an edge of the first encapsulation layer TFE1 and the first partition wall SW1 (or the second sub-partition wall SW_S2).

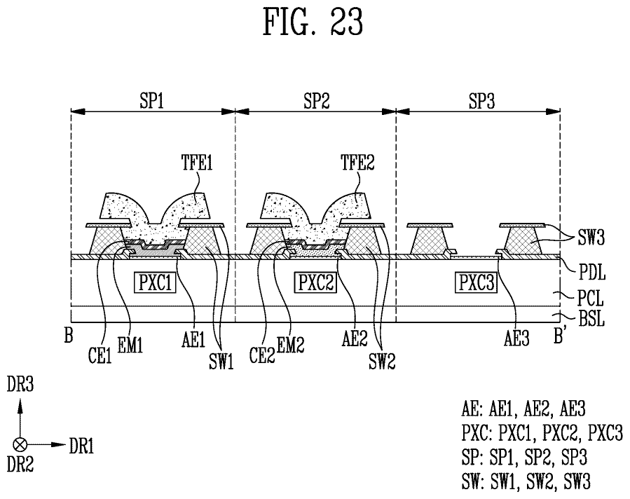

Referring to FIG. 23, a second light-emitting layer EM2, a second cathode electrode CE2, and a second encapsulation layer TFE2 may be formed on the second anode electrode AE2.

A process of forming the second light-emitting layer EM2, the second cathode electrode CE2, and the second encapsulation layer TFE2 is substantially the same as or similar to the process of forming the first light-emitting layer EM1, the first cathode electrode CE1, and the first encapsulation layer TFE1 described with reference to FIGS. 21 and 22, and thus redundant descriptions will be omitted.

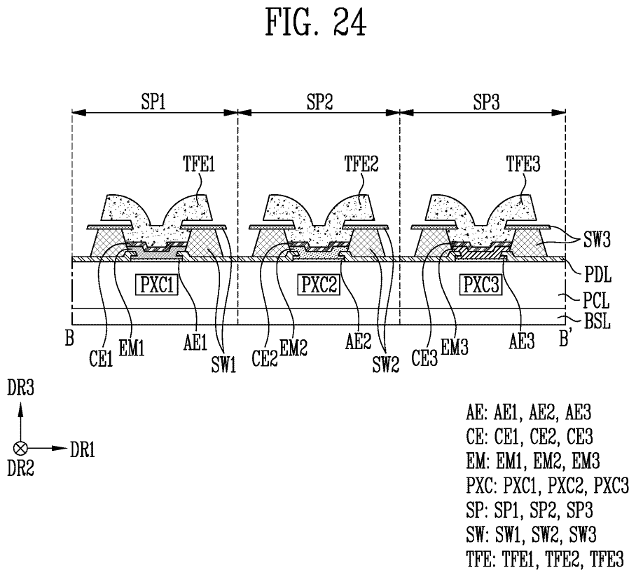

Referring to FIG. 24, a third light-emitting layer EM3, a third cathode electrode CE3, and a third encapsulation layer TFE3 may be formed on the third anode electrode AE3.

The process of forming the third light-emitting layer EM3, the third cathode electrode CE3, and the third encapsulation layer TFE3 is substantially the same as or similar to the process of forming the first light-emitting layer EM1, the first cathode electrode CE1, and the first encapsulation layer TFE1 described with reference to FIGS. 21 and 22, and thus redundant descriptions will be omitted.

Subsequently, an organic layer OL and an upper encapsulation layer UE may be formed to complete the display panel of FIG. 8.

A display device according to one or more embodiments is applicable to various types of electronic devices. In one or more embodiments, an electronic device includes the above-described display device and may further include other modules or devices having additional functions in addition to the display device.

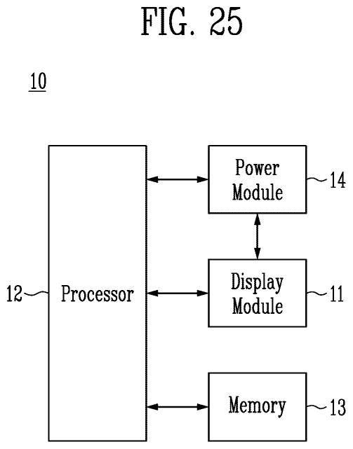

FIG. 25 is a block diagram of an electronic device according to one or more embodiments. Referring to FIG. 25, an electronic device 10 according to one or more embodiments may include a display module 11 (or a display device), a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals, and may output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

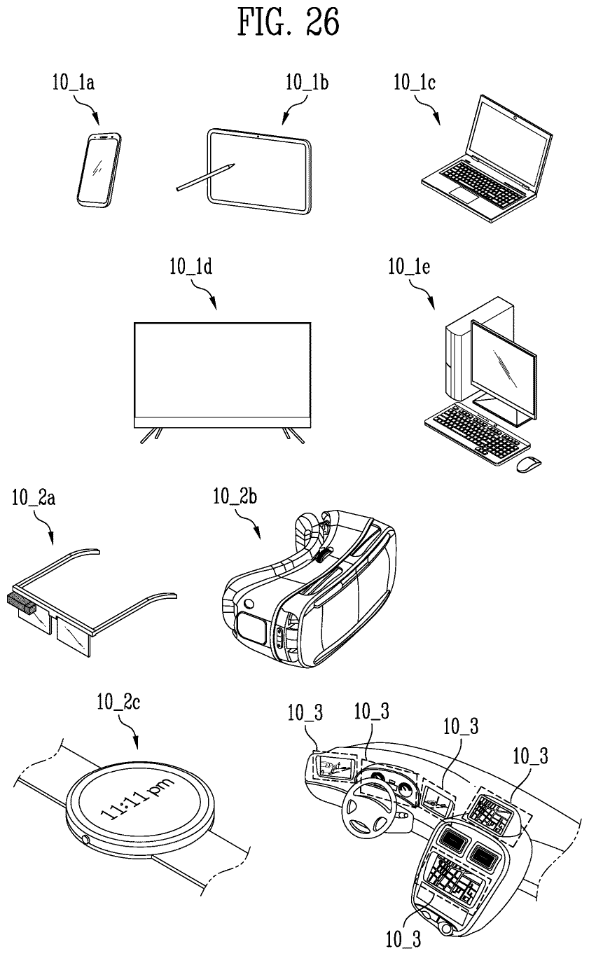

FIG. 26 is a schematic diagram of an electronic device according to various embodiments.

Referring to FIG. 26, various types of electronic devices to which embodiments of a display device are applied may include an electronic device to display images, such as a smartphone 10_1a, a tablet PC 10_1b, a laptop computer 10_1c, a television (TV) 10_1d, or a desktop monitor 10_1e, a wearable electronic device including a display module, such as smart glasses 10_2a, a head-mounted display (HMD) 10_2b, or a smart watch 10_2c, or an automotive electronic device 10_3 including a display module, such as a center information display (CID) located at the instrument cluster, the center fascia, and/or the dashboard of a vehicle, or a room mirror display.

Accordingly, the spirit of the present disclosure should not be limited to the embodiments described, and all equivalent or equivalent modifications to the claims as well as the claims described below fall within the scope of the spirit of the present disclosure.

What is claimed is:

1. A display device comprising:
a first electrode defining first openings;
first light-emitting elements respectively in the first openings and configured to emit light in a first color;
a second electrode defining second openings;
second light-emitting elements respectively in the second openings and configured to emit light in a second color;
a third electrode defining third openings; and
third light-emitting elements respectively in the third openings and configured to emit light in a third color,
wherein the first electrode, the second electrode, and the third electrode are separated from each other and are electrically disconnected.

2. The display device of claim 1, wherein the first light-emitting elements are configured to receive a first voltage through the first electrode,
wherein the second light-emitting elements are configured to receive a second voltage through the second electrode, and
wherein the third light-emitting elements are configured to receive a third voltage through the third electrode.

3. The display device of claim 1, wherein no electrode is between the first electrode and the second electrode or between the second electrode and the third electrode in a plan view.

4. The display device of claim 1, wherein, in a plan view, the first electrode, the second electrode, and the third electrode are sequentially arranged along a first direction, and extend in a second direction crossing the first direction,
wherein the first openings, the second openings, and the third openings are arranged along the second direction, and
wherein, in a plan view, the first electrode surrounds only the first light-emitting elements, the second electrode surrounds only the second light-emitting elements, and the third electrode surrounds only the third light-emitting elements.

5. The display device of claim 1, wherein, in a plan view, the first electrode, the second electrode, and the third electrode are sequentially and repeatedly arranged along a first direction, and extend in a second direction crossing the first direction, and
wherein the first openings, the second openings, and the third openings are arranged along the second direction.

6. The display device of claim 1, wherein the first light-emitting element, the second light-emitting element, and the third light-emitting element comprise an anode electrode, a light-emitting layer above the anode electrode, and a cathode electrode above the light-emitting layer,
wherein the first electrode contacts the cathode electrode of the first light-emitting elements,
wherein the second electrode contacts the cathode electrode of the second light-emitting elements,
wherein the third electrode contacts the cathode electrode of the third light-emitting elements,
wherein the display device further comprises:
an encapsulation layer above the cathode electrode at the first opening, the second opening, and the third opening;
an organic layer above and covering the encapsulation layer; and
a pixel-defining layer above the anode electrode and defining openings corresponding to the first opening, the second opening, and the third opening, and
wherein the organic layer fills between the first electrode, the second electrode, and the third electrode, and contacts the pixel-defining layer between the first electrode, the second electrode, and the third electrode.

7. The display device of claim 1, wherein the first light-emitting elements correspond one-to-one with the first openings,
wherein the second light-emitting elements correspond one-to-one with the second openings, and
wherein the third light-emitting elements correspond one-to-one with the third openings.

8. The display device of claim 1, wherein the first light-emitting element, the second light-emitting element, and the third light-emitting element comprise an organic light-emitting diode.

9. A display device comprising:
a first electrode defining first openings;
first light-emitting elements respectively in the first openings and configured to emit light in a first color;
a second electrode defining second openings and third openings, and electrically separated from the first electrode;
second light-emitting elements respectively in the second openings and configured to emit light in a second color; and
third light-emitting elements respectively in the third openings and configured to emit light in a third color.

10. The display device of claim 9, wherein the first light-emitting elements emit light in blue,
wherein the second light-emitting elements emit light in red, and
wherein the third light-emitting elements emit light in green.

11. The display device of claim 9, wherein, in a plan view, the first electrode and the second electrode are spaced apart from each other in a first direction, and extend in a second direction crossing the first direction, and
wherein the first openings, the second openings, and the third openings are arranged along the second direction.

12. The display device of claim 11, wherein the first electrode and the second electrode are alternately and repeatedly arranged along the first direction,
wherein the first electrode is connected to another first electrode at one end, and
wherein the second electrode is connected to another second electrode at another end.

13. The display device of claim 11, wherein the second openings and the third openings are alternately arranged along the second direction.

14. The display device of claim 9, wherein the first light-emitting element, the second light-emitting element, and the third light-emitting element comprise an anode electrode, a light-emitting layer above the anode electrode, and a cathode electrode above the light-emitting layer,
wherein the first electrode contacts the cathode electrode of the first light-emitting elements,
wherein the second electrode contacts the cathode electrode of the second and third light-emitting elements, and
wherein the display device further comprises:
a pixel-defining layer above the anode electrode and defining openings corresponding to the first opening, the second opening, and the third opening;
an encapsulation layer above the cathode electrode at the first opening, the second opening, and the third opening; and
an organic layer above the encapsulation layer and covering the encapsulation layer, and
wherein the organic layer fills between the first electrode and the second electrode and contacts the pixel-defining layer.

15. An electronic device comprising:
a processor configured to provide image data; and
a display device configured to display an image based on the image data, and comprising:
a first electrode defining first openings;
first light-emitting elements respectively in the first openings and configured to emit light in a first color;
a second electrode defining second openings and electrically separated from the first electrode; and
a second light-emitting element respectively in the second openings and configured to emit light in a second color.

16. The electronic device of claim 15, wherein the first and second light-emitting elements comprise an anode electrode, a light-emitting layer above the anode electrode, and a cathode electrode above the light-emitting layer,
wherein the first electrode contacts the cathode electrode of the first light-emitting elements,
wherein the second electrode contacts the cathode electrode of the second light-emitting elements, and
wherein the electronic device further comprises:
a pixel-defining layer above the anode electrode and defining openings corresponding to the first and second openings;
an encapsulation layer above the cathode electrode at the first and second openings; and
an organic layer above the encapsulation layer, covering the encapsulation layer, filling between the first electrode and the second electrode, and contacting the pixel-defining layer.

17. The electronic device of claim 15, further comprising:
a third electrode defining third openings and electrically separated from the first electrode and the second electrode; and
third light-emitting elements respectively in the third openings and configured to emit light in a third color,
wherein, in a plan view, the first electrode, the second electrode, and the third electrode are sequentially arranged along a first direction, and extend in a second direction crossing the first direction, and
wherein the first openings, the second openings, and the third openings are arranged along the second direction.

18. The electronic device of claim 15, further comprising third light-emitting elements respectively in third openings defined in the second electrode and configured to emit light in green,
wherein the first light-emitting elements emit light in blue, and
wherein the second light-emitting elements emit light in red.

19. The electronic device of claim 15, further comprising third light-emitting elements respectively in third openings defined in the second electrode and configured to emit light in a third color,
wherein, in a plan view, the first electrode and the second electrode are spaced apart from each other and alternately and repeatedly arranged in a first direction, and extend in a second direction crossing the first direction,
wherein the first openings, the second openings, and the third openings are arranged along the second direction,
wherein the first electrode is connected to another first electrode at one end, and
wherein the second electrode is connected to another second electrode at another end.

20. The electronic device of claim 15, further comprising third light-emitting elements respectively in third openings defined in the second electrode and configured to emit light in a third color,
wherein, in a plan view, the first electrode and the second electrode are spaced apart from each other in a first direction, and extend in a second direction crossing the first direction, and
wherein the first openings, the second openings, and the third openings are arranged along the second direction, the second openings and the third openings being alternately arranged along the second direction.
